(19) United States
(12) Patent Application Publication
(10) Pub. No.: US 2011/0195237 A1
(43) Pub. Date: Aug. 11, 2011

(54) SYSTEM AND RESIN FOR RAPID PROTOTYPING

(75) Inventors: Ranjana C. Patel, Little Hallingury (GB); Jean-Jacques Lagref, Basel (CH); Zoubai M. Cherkaoui, Allschwil (CH); Carole Chapelat, Saint Louis (FR); Richard Frantz, Bartenheim (FR); Michael Rhodes, Reinach (CH); Beat Dobler, Allschwil (CH)

(73) Assignee: Huntsman International LLC, The Woodlands, TX (US)

(21) Appl. No.: 13/123,650

(22) PCT Filed: Sep. 15, 2009
(86) PCT No.: PCT/EP2009/061958

§ 371 Date: Apr. 11, 2011

(30) Foreign Application Priority Data
Oct. 17, 2008 (EP) 08018228.0

(51) Int. Cl. B32B 3/10; G03B 27/54; G03F 7/004; G03F 7/20

(52) U.S. Cl. 428/195.1; 355/67; 430/284.1; 430/322

(57) ABSTRACT

The present invention relates to a system and a resin relating to rapid prototyping.

The System comprises:

(a) an apparatus for producing a three-dimensional object from a light-sensitive material, wherein input optics (IO) and output optics (OO) facilitates transmission of light emitted from an illumination source via individually controllable light modulators (LM) of spatial light modulator (SLM) to an illumination area (IA), wherein said output optics (OO) enable focusing of the pattern of light from spatial light modulators (SLM) on an illumination area (IA); and

(b) a resin composition comprising:

(A) an acrylate component with

(B) a methacrylate component and

(C) a photo initiator.

### CROSS-REFERENCE TO RELATED APPLICATIONS

1. Field of the Invention

The present invention relates to a system and a resin for rapid prototyping and manufacturing of three-dimensional objects by additive treatment of cross-sections.

2. Background

In three-dimensional rapid prototyping, it is important that the optics of the exposure system is not contaminated from contact with the light-sensitive material, which could possibly cause time-intensive cleaning or even replacement. Hence typically a relatively large distance between the output optics and the illumination area is preferred in order to avoid risk of contact between the exposure system and the light-sensitive material.

A high intensity laser spot is therefore conventionally used to irradiate the surface of a layer of a liquid curable light sensitive material according to a predefined pattern, so as to generate layer wise the required solid three-dimensional objects. After this first curing with the laser, the solidified object exhibits a so called green strength, i.e. a strength enabling the article to be self-supporting. Later, such object is post-cured with high intensity ultraviolet (UV) lamps to achieve its optimal mechanical properties.

The process of irradiating the surface of the photo curable liquid with a high energy laser spot does not allow, however, large surfaces to be cured fast and with accuracy. Furthermore, the delivery of a high amount of energy in a short time on a very small surface via a laser beam produces high thermal and mechanical stresses in the material, leading to high shrinkage and curling. In addition, a laser emits only at a very specific wavelength, at which only few specific photo initiators are active and can be used.

If incoherent UV light sources are to be used instead of lasers, said sources will exhibit necessarily lower radiation intensity. Masks with low intensity incoherent UV light sources distributed over a large surface must therefore be introduced (WO 00121735, EP 1250997).

The use of such equipments, however, causes the problem that such non-coherent low intensity radiation cannot achieve the same curing speeds as high intensity laser radiation and requires the use of much faster-curing resin compositions to provide sufficient green strength to enable the article to be self-supporting, while being built and before a final UV flood cure following removal from the bath in which it is built. WO 2005/092598 describes acrylic based formulations with high curing speed.

However, the fast-curing polymers tend to be brittle and shrink substantially on curing, thereby degrading the accuracy of the model and causing parts of the model to curl.

The problem to be solved by the present invention is to provide a system for rapid prototyping able to cure large surfaces in short time with high accuracy, whereby the produced articles exhibit high green strength, good mechanical properties, high toughness and low curling and shrinkage.

The problem has been solved according to the features of independent claims 1 and 11.

### DESCRIPTION OF THE INVENTION

System

The invention relates to a system for producing a three-dimensional object from a light-sensitive material, said system comprising:

an exposure system with an illumination source,

a control unit,

whereby said exposure system comprises:

at least one spatial light modulator with a plurality of individually controllable light modulators,

input optics optically coupled to said at least one spatial light modulator,

output optics optically coupled to said at least one spatial light modulator,

wherein said input optics and output optics facilitates transmission of light emitted from said illumination source via said individually controllable light modulators of said spatial light modulator to an illumination area,

wherein said spatial light modulator enables an establishment of a pattern of the light transmitted through said input optics, according to control signals originating from said control unit,

wherein said output optics enable focusing of the pattern of light from said at least one spatial light modulator on an illumination area.

The system comprises additionally as a light sensitive material a resin composition comprising:

(A) at least one acrylate component with

(B) at least one methacrylate component and

(C) a photoinitiator.

According to a preferred embodiment of the invention, the distance d between the output optics and the illumination area is between 0.5 and 20 mm and/or the illumination source generates incoherent light.

In a further advantageous embodiment of the invention, the apparatus comprises a scanning bar which facilitates that the exposure system can be moved and scanned across the surface of the light-sensitive material in order to illuminate and irradiate the desired portions of said light-sensitive material.

In three-dimensional rapid prototyping, if the output optics of the exposure system is just shortly in contact with the light-sensitive material, this may cause contamination of the output optics such that the output optics needs time-intensive cleaning or even replacement. Hence typically a relatively large distance between the output optics and the illumination area is preferred in order to avoid risk of contact between the exposure system and the light-sensitive material.

With such arrangements even small inaccuracies between the directions of individual light beams may be a serious problem and may cause some voxels to deviate from the intended position. In order to decrease the troubles with alignment of multiple beams, significant effort has been put into improving the alignment through modification of the design of the optics. Even though improvements have been observed in this way, there is a need for even better alignment of the individual light beams.

According to a preferred embodiment of the present invention it has been shown that advantageous reductions of adverse consequences of misalignment can be observed by lowering the distance between the output optics and the light-sensitive material to values between 0.5 and 20 mm. This is made possible through the use of output optics with characteristics such that the individual light beams are focused at a suitable low distance from the part of the output optics closest to the light-sensitive material. Hereby production costs in the design of the optics may be reduced without risking the efficiency of the apparatus. The foci from the light beams together establish an illumination area, which during manufacturing will at least partly flush with the upper surface of the light-sensitive material.

Furthermore, by lessening the distance between output optics and light-sensitive material, further beneficial advantages are seen as well. A larger part of the intensity of the light is transferred to the light-sensitive material, which facilitates a faster solidification of the illuminated voxels and thus in turn facilitates a faster scanning process. Hereby a more efficient three-dimensional object manufacturing is obtained.

20 mm has been established as the largest distance where the advantageous above-mentioned results may be obtained. 0.5 mm has been established as the shortest applicable distance without having too high risk of contact with the resin.

It has been observed according to embodiments of the present invention that other means may be used to avoid contact between the exposure system and the light-sensitive material, whereby the previously feared problems with low distances need not cause that such distances are not used.

The illumination source of the present invention can emit radiation in the range from deep UV to far IR, e.g. from 200 nm to 100000 nm. The term light applies therefore to radiation in the range from deep UV to far IR, e.g. from 200 nm to 100000 nm. Applications using stereo lithographic baths of curable liquid resins are preferably carried out in the ultra violet energy range with wavelength from 200 nm up to 500 nm.

In a preferred embodiment of the invention, the apparatus of the system further comprises a vat for containing the light-sensitive material. However, roll-to-roll web deposition without a vat may be used as well.

The system according to the present invention preferably comprises a vat comprising the light-sensitive material, i.e. a curable resin composition, in an amount so that the surface of said light-sensitive material substantially coincides with the illumination area.

The preferred distance between said output optics and said surface of said light-sensitive material is in this case between 0.5 mm and 20 mm, preferably between 1 mm and 10 mm.

With a low distance between output optics and illumination area, the system must cure the surface of the bath of the curable resin composition with a relatively large illumination area generated by a low-energy incoherent light.

As previously mentioned, the exposure system may move above the resin with a small distance when it is performing a scan to expose the surface of the resin. Due to this very small distance there is a risk of contamination with resin on the bottom surface of the exposure system during the scan across the resin surface. Such contamination may e.g. stems from parts of the built product, which during manufacturing may protrude slightly from the surface. This may e.g. be caused by the fact that a recoater accidentally touches the part on the building plate, or, for some resins, that stress in the already built lower-laying layers may cause unevenness of the built surface of the previous layer. The contamination may also arise due to poor layer quality as a result of recoating, for example, parts including trapped volumes and large flat areas.

If the exposure system touches a protruding part the bottom surface of the exposure system will be contaminated with resin. Consequently the surface must be cleaned from resin before the exposure can be resumed, and the cleaning is a time consuming and expensive process. Furthermore there is a risk of contamination or damage to the micro-optics and SLM-modules in the exposure system.

As a consequence, there is a need for avoiding or decreasing contamination on the bottom surface.

According to a preferred embodiment of the present invention, the system of the present invention therefore comprises at least one releasable protective window between the output optics and the illumination area.

The present rapid prototyping system is capable of illumination with multiple beams, where the multiple beams are desired to be protected and hence some kind of protection is desired. However, the inclusion of a protective window in the path of the multiple beams introduces possible troublesome alignment issues as light propagating through different media will tend to loose intensity and the light beams will be displaced when travelling through the interface between different media.

Displacement of light beams due to media transitions may be problematic in any kind of rapid prototyping apparatus; however, the displacement is especially problematic when a multiple beam apparatus is used in comparison to e.g. a single beam laser system, where issues concerning individual deviating displacements between different beams do not arise.

According to the present invention it has been observed that troubles with light travelling through a protective window may be avoided by moving the exposure system close to the light-sensitive material. For example, it may be advantageous when the distance from the output optics is less than 10 mm from the light-sensitive material.

According to embodiments of the invention, the protective window is releasable, in order to facilitate an easy replacement of the protective window if the protective window has been contaminated or greased.

Alternative and additional methods are possible to avoid or decrease contamination on the bottom surface and in particular to avoid collision between the exposure system and possible protrusions in the resin.

The apparatus of the system according to the present invention may comprise preferably at least one collision-preventing detection system for detecting obstacles between the illumination area and the output optics.

In three-dimensional rapid prototyping, if e.g. the output optics of the exposure system is just shortly in contact with e.g. obstacles, this may cause contamination of the output optics such that the output optics needs time-intensive cleaning or even replacement. Hence a need exists to aid in preventing contact between parts of the exposure system and obstacles, such as the light-sensitive material or protrusions from the vat.

An important feature of the preferred embodiment of the present invention is that it is a collision-preventing detection system. I.e. a possible future collision is detected before it actually occurs, which means that neither the exposure system nor any other component of the apparatus is damaged or contaminated due to e.g. an obstacle protruding from the surface of the vat.

In this way, the time wasted on stopping the system may be highly reduced in that an obstacle protruding from the surface of the vat may be detected and removed without contaminating the apparatus as compared to prior art, where an obstacle may cause contamination of the apparatus resulting in a time-consuming cleaning process or alternatively an expensive replacement of at least a part of the elements of the apparatus.

The collision-preventing detection system according to the present invention is especially advantageous in exposure systems, where the distance between the exposure system and the surface of the light-sensitive material is kept relatively low, for example between 0.5 and 20 mm. This means that even very small protrusions from the surface may be problematic and must be detected in time.

In an embodiment of the invention, said collision-preventing detection system comprises at least one light emitter and at least one light sensor capable of providing at least one collision-preventing light beam.

According to an advantageous embodiment of the invention, the collision-preventing detection system comprises a light beam scanning the surface of the light-sensitive material in a suitable distance from the surface, i.e. 1 mm. This light beam may be emitted from a various number of illumination sources well-known to the skilled person, e.g. a laser. After crossing the relevant surface the light beam is detected by a light sensor, which is able to detect whether the intensity of the light beam drops as a result of the fact that the light beam strikes an obstacle such as a protrusion from the surface.

The beam of light is typically positioned in front of the scanning bar, but between the resin surface and the bottom surface of the scanning bar.

According to a preferred embodiment of the invention, the light sensor and light emitter are both mounted directly on the exposure system. Hereby the sensor and emitter move simultaneously with the scanning bar, whereby a sensing for possible obstacles in an area of the resin surface may be carried out immediately before the exposure system reaches that area of the resin surface.

In an embodiment of the invention, the exposure system comprises one or more light-emitting diodes as illumination sources.

According to an embodiment of the invention more than one light-emitting diode is used to increase the intensity of emitted light. With an increased intensity of light it is possible to increase the scanning speed of the exposure system across the illumination area.

In an embodiment of the invention, light from one specific light-emitting diode is illuminating one specific spatial light modulator.

According to an embodiment of the invention one specific light-emitting diode is then dedicated to one specific spatial light modulator. This may be very advantageous because it then becomes possible to completely turn off one light-emitting diode if patterned light from one of the spatial light modulators does not have to be used to build one layer of an object. Turning off one light-emitting diode reduces the energy consumption as well as the generation of heat.

According to an embodiment of the invention the relationship between the light-emitting diodes and the spatial light modulators is a one to one relationship. This one to one relationship adds a high degree of flexibility e.g. enables the exposure system to turn on or off each individual spatial light modulator.

However, light-emitting diodes arrays can be used as a direct illumination source and their light can be focused directly onto the illumination area without the need of spatial light modulators.

In an embodiment of the invention, said apparatus facilitates that said exposure system is scanned and moved across said light-sensitive material, so as to irradiate the required areas of the curable resin.

In an advantageous embodiment of the invention the exposure system is scanned and moved across a light-sensitive material. The spatial light modulators pattern light to cure an illumination area on the light-sensitive material, when the exposure system is scanned across the light-sensitive material. The exposure head is scanned across the light-sensitive material at least one time per layer of the object to be built and irradiates areas of the curable resin.

Resin Composition

Part of the inventive system is a resin composition according to the claims.

According to the invention, the system comprises a resin composition comprising:
(A) at least one acrylate component with
(B) at least one methacrylate component and
(C) a photo initiator

According to a preferred embodiment of the present invention, the resin composition of the system comprises:
(A) 15-40% by weight of at least two different acrylate components
(B) 50-80% by weight of at least two different methacrylate components
(C) 0.1-7% by weight of a photo initiator
based on the total weight of the resin composition.

According to a preferred embodiment of the present invention an acrylate component is an aliphatic or cycloaliphatic acrylate, preferably a cycloaliphatic diacrylate, or any mixture thereof.

In particular, an acrylate component may be a polyethylenglycol acrylate, preferably a polyethylenglycol diacrylate.

It has been surprisingly found that the combination of (A), (B) and (C) results in a photocurable composition which exhibits high curing speed, high green strength, low shrinkage, high toughness and good mechanical properties of the produced 3-D objects, so that such composition is particularly suited to be used in an apparatus characterized by the features as described above.

According to a preferred embodiment of the present invention a methacrylate component is an aliphatic urethane methacrylate.

According to a preferred embodiment of the present invention a methacrylate component is an ethoxylated bisphenol methacrylate, preferably an ethoxylated bisphenol dimethacrylate

According to a preferred embodiment of the present invention, the resin composition of the system comprises additionally a multifunctional thiol, preferably in an amount of 0.1-10% by weight, more preferably 1-8% by weight based on the total weight of the composition.

The addition of multifunctional thiols to the resin composition surprisingly increases dramatically the green strength and the toughness of the produced objects and reduces drastically the shrinkage.

According to a preferred embodiment of the present invention, the resin composition of the system comprises additionally a stabilizer, preferably a N-nitroso hydroxyl amine complex. with the structure:

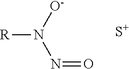

whereby R is an aromatic hydrocarbon rest and S⁺ is a salt.

In particular, the nitroso hydroxyl amine complex may be an aluminium salt complex.

Another object of the present invention relates to a resin composition comprising at least an acrylate component (A), an aliphatic urethane methacrylate component (B) and a photo initiator (C).

It has been surprisingly found that the combination of (A), (B) and (C) results in a photocurable composition which exhibits high curing speed, high green strength, low shrinkage, high toughness and good mechanical properties of the produced 3-D objects, so that such composition is particularly suited to be used in an apparatus characterized by the features as described above.

The resin composition comprises preferably:
(A) a polyethylenglycol diacrylate or a cycloaliphatic diacrylate or any mixture thereof and/or
(D) a multifunctional thiol.

In particular, the resin composition comprises preferably at least:
(A) 5-60% by weight of at least one acrylate component, preferably polyethylenglycol diacrylate and/or a cycloaliphatic diacrylate
(B) 20-50% % by weight of at least an aliphatic urethane methacrylate
(C) 0.5-5% by weight of a photo initiator
(D) optionally a multifunctional thiol,
based on the total weight of the composition.

In a preferred embodiment the resin composition comprises at least:
(A1) 5-15% by weight of a polyethylenglycol diacrylate
(A2) 5-15% by weight of an aliphatic or cycloaliphatic diacrylate
(B1) 20-50% % by weight of an aliphatic urethane methacrylate.
(B2) 20-50% % by weight of an ethoxylated bisphenol methacrylate.
(C) 0.5-5% by weight of a photo initiator
(D) 0.1-10% by weight of a multifunctional thiol
(E) 0.01 to 0.5% % by weight of a stabilizer
based on the total weight of the composition.

The addition of multifunctional thiols to the resin composition unexpectedly increases significantly the green strength and the toughness of the produced objects and reduces notably their shrinkage.

(A) Acrylate Components

In the following paragraph, suitable acrylate components for resin compositions according to the present invention are listed. An acrylate component may refer to a single acrylate compound or to a mixture of different acrylate compounds. Suitable acrylate components can be monofunctional, difunctional or of higher functionality.

Monofunctional acrylates may be used to modify resin properties.

Examples of monofunctional acrylates include such as isobornyl acrylate, tetrahydrofurfuryl acrylate, ethoxylated phenyl acrylates, lauryl acrylate, stearyl acrylate, octyl acrylate, isodecyl acrylate, tridecyl acrylate, caprolactone acrylate, nonyl phenol acrylate, cyclic trimethylolpropane formal acrylate, methoxy polyethyleneglycol acrylates, methoxy polypropyleneglycol acrylates, hydroxyethyl acrylate, hydroxypropyl acrylate, glycidyl acrylate. This list is not exhaustive and in each case ethoxylation and/or propoxylation of those acrylates can be used to modify properties further.

According to a preferred embodiment of the invention, acrylates are difunctional. Examples of preferred aliphatic or cycloaliphatic diacrylates include tricyclodecane dimethanol diacrylate (Sartomer® 833s), dioxane glycerol diacrylate (Sartomer® CD 536), 1,6 hexanediol diacrylate (Sartomer® 238), 3-methyl 1,5-pentanediol diacrylate (Sartomer® 341), tripropylene glycol diacrylate (Sartomer® 306), Neopentyl glycol diacrylate (Sartomer® 247), dimethyloltricyclodecane diacrylate (Kayarad R-684), 1,4-dihydroxymethylcyclohexane diacrylate, 2,2-bis(4-hydroxy-cyclohexyl)propane diacrylate, bis(4-hydroxycyclohexyl)methane diacrylate. Examples of acyclic aliphatic diacrylates include compounds of the formulae (F-I) to (F-IV) of U.S. Pat. No. 6,413,697, herein incorporated by reference. Further examples of possible diacrylates are compounds of the formulae (F-V) to (F-VIII) of U.S. Pat. No. 6,413,697. Their preparation is also described in EP-A-0 646 580, herein incorporated by reference. Some compounds of the formulae (F-I) to (F-VIII) are commercially available. This list is not exhaustive and in each case ethoxylation and/or propoxylation of those diacrylates can be used to modify properties further.

Examples of aromatic diacrylates include bisphenol A polyethylene glycol diether diacrylate (Kayarad R-551), 2,2′-methylenebis[p-phenylenepoly(oxyethylene)oxy]-diethyl diacrylate (Kayarad R-712), hydroquinone diacrylate, 4,4′-dihydroxybiphenyl diacrylate, Bisphenol A diacrylate, Bisphenol F diacrylate, Bisphenol S diacrylate, ethoxylated or propoxylated Bisphenol A diacrylate, ethoxylated or propoxylated Bisphenol F diacrylate, ethoxylated or propoxylated Bisphenol S diacrylate, bisphenol-A epoxy diacrylate (Ebecryl® 3700 UCB Surface Specialties).

Examples of preferred polyethlenglycol diacrylates used in resins according to the invention are traethyleneglycol diacrylate (Sartomer® 268), polyethleneglycol(200) diacrylate (Sartomer® 259), polyethleneglycol(400) diacrylate (Sartomer® 344). This list is not exhaustive and in each case ethoxylation and/or propoxylation of those diacrylates can be used to modify properties further.

Examples of triacrylate or a acrylate with even higher functionality are hexane-2,4,6-triol triacrylate, glycerol triacrylate, 1,1,1-trimethylolpropane triacrylate, ethoxylated or propoxylated glycerol triacrylate, ethoxylated or propoxylated 1,1,1-trimethylolpropane triacrylate, pentaerythritol tetraacrylate, bistrimethylolpropane tetraacrylate, pentaerythritol monohydroxytriacrylate, dipentaerythritol monohydroxypentaacrylate, dipentaerythritol pentaacrylate (Sartomer® 399), pentaerythritol triacrylate (Sartomer® 444), pentaerythritol tetracrylate (Sartomer® 295), trimethylolpropane triacrylate (Sartomer® 351), tris(2-acryloxy ethyl) isocyanurate triacrylate (Sartomer® 368), ethoxylated (3) trimethylolpropane triacrylate (Sartomer® 454), dipentaerythritol pentaacrylate ester (Sartomer® 9041), Examples of suitable aromatic triacrylates are the reaction products of triglycidyl ethers of trihydric phenols, and phenol or cresol novolaks containing three hydroxyl groups, with acrylic acid. This list is not exhaustive and in each case ethoxylation and/or propoxylation of those triacrylates can be used to modify properties further.

A polyacrylate may also be a polyfunctional urethane acrylate. Urethane acrylates may be prepared by, e.g., reacting a hydroxyl-terminated polyurethane with acrylic acid, or by reacting an isocyanate-terminated prepolymer with hydroxyalkyl acrylates to give the urethane acrylate. Preferred are urethane acrylates made from polyester diols, aliphatic isocyanates and hydroxyalkyl acrylates. Also preferred are those having polyfunctionality of acrylates or mixed acrylic and methacrylic functionality.

Furthermore, higher functionality acrylates, including hyberbranched polyester types, may also be used for resin modification. Commercially available examples include such as CN2301, CN2302, CN2303, CN2304 from Sartomer.

Additional examples of acrylates can be used in the formulation include such as D-310, D-330, DPHA-2H, DPHA-2C, DPHA-21, DPCA-20, DPCA-30, DPCA-60, DPCA-120, DN-0075, DN-2475, T-2020, T-2040, TPA-320, TPA-330 1-1420, PET-30, THE-330 and RP-1040 from Kayarad, R-526, R-604, R-011, R-300 and R-205 from Nippon Kayaku Co. Ltd., Aronix M-210, M-220, M-233, M-240, M-215, M-305, M-309, M-310, M-315, M-325, M-400, M-6200 and M-6400 from Toagosei Chemical Industry Co, Ltd., Light acrylate BP-4EA, BP-4PA, BP-2EA, BP-2PA and DCP-A from Kyoeisha Chemical Industry Co. Ltd., New Frontier BPE-4, TEICA, BR-42M and GX-8345 from Daichi Kogyo Seiyaku Co. Ltd., ASF-400 from Nippon Steel Chemical Co. Ltd., Ripoxy SP-1506, SP-1507, SP-1509, VR-77, SP-4010 and SP-4060 from Showa Highpolymer Co. Ltd., NK Ester A-BPE-4 from Shin-Nakamura Chemical Industry Co. Ltd., SA-1002 from Mitsubishi Chemical Co. Ltd., Viscoat-195, Viscoat-230, Viscoat-260, Viscoat-310, Viscoat-214HP, Viscoat-295, Viscoat-300, Viscoat-360, Viscoat-GPT, Viscoat-400, Viscoat-700, Viscoat-540, Viscoat-3000 and Viscoat-3700 from Osaka Organic Chemical Industry Co. Ltd

(B) Methacrylate Components

In the following, suitable methacrylate components for resin compositions according to the present invention are listed. A methacrylate component may refer to a single methacrylate compound or to a mixture of different methacrylate compounds. Suitable methacrylate components can be monofunctional, difunctional or of higher functionality.

Monofunctional methacrylates may be used to modify resin properties.

Examples of monofunctional methacrylate include isobornyl methacrylate, tetrahydrofurfuryl methacrylate, ethoxylated phenyl methacrylate, lauryl methacrylate, stearyl methacrylate, octyl methacrylate, isodecyl methacrylate, tridecyl methacrylate, caprolactone methacrylate, nonyl phenol methacrylate, cyclic trimethylolpropane formal methacrylate, methoxy polyethyleneglycol methacrylates, methoxy polypropyleneglycol methacrylates, hydroxyethyl methacrylate, hydroxypropyl methacrylate, glycidyl methacrylate. This list is not exhaustive and in each case ethoxylation and/or propoxylation of those methacrylates can be used to modify properties further

Examples of preferred aromatic dimethacrylates used in resins according to the invention include ethoxylated (2) bisphenol A dimethacrylate (Sartomer® 101K), ethoxylated (2) bisphenol A dimethacrylate (Sartomer® 348L), ethoxylated (3) bisphenol A dimethacrylate (Sartomer® 348C), ethoxylated (4) bisphenol A dimethacrylate (Sartomer® 150), ethoxylated (4) bisphenol A dimethacrylate (Sartomer® 540), ethoxylated (10) bisphenol A dimethacrylate (Sartomer®480), hydroquinone dimethacrylate, 4,4′-dihydroxybiphenyl dimethacrylate, Bisphenol A dimethacrylate, Bisphenol F dimethacrylate, Bisphenol S dimethacrylate, ethoxylated or propoxylated Bisphenol A dimethacrylate, ethoxylated or propoxylated Bisphenol F dimethacrylate, and ethoxylated or propoxylated Bisphenol S dimethacrylate.

Examples of aliphatic or cycloaliphatic dimethacrylates include 1,4-dihydroxymethylcyclohexane dimethacrylate, 2,2-bis(4-hydroxy-cyclohexyl)propane dimethacrylate, bis(4-hydroxycyclohexyl)methane,

Examples of acyclic aliphatic dimethacrylates include compounds of the formulae (F-I) to (F-IV) of U.S. Pat. No. 6,413,697, herein incorporated by reference. Further examples of possible dimethacrylates are compounds of the formulae (F-V) to (F-VIII) of U.S. Pat. No. 6,413,697. Their preparation is also described in EP-A-0 646 580, herein incorporated by reference. Some compounds of the formulae (F-I) to (F-VIII) are commercially available. This list is not exhaustive and in each case ethoxylation and/or propoxylation of those dimethacrylates can be used to modify properties further

Examples of trimethacrylate or a methacrylate with even higher functionality include such as tricyclodecane dimethanol dimethacrylate (Sartomer® 834), trimethylolpropane trimethacrylate (Sartomer® 350), tetramethylolmethane tetramethacrylate (Sartomer® 367), hexane-2,4,6-triol trimethacrylate, glycerol trimethacrylate, 1,1,1-trimethylolpropane trimethacrylate, ethoxylated or propoxylated glycerol trimethacrylate, ethoxylated or propoxylated 1,1,1-trimethylolpropane trimethacrylate, pentaerythritol tetramethacrylate, bistrimethylolpropane tetramethacrylate, pentaerythritol monohydroxytrimethiacrylate, dipentaerythritol monohydroxypentamethacrylate, Examples of suitable aromatic trimethacrylates are the reaction products of triglycidyl ethers of trihydric phenols, and phenol or cresol novolaks containing three hydroxyl groups, with methacrylic acid. This list is not exhaustive and in each case ethoxylation and/or propoxylation of those methacrylates can be used to modify properties further. Examples of suitable aromatic trimethacrylates are the reaction products of triglycidyl ethers of trihydric phenols, and phenol or cresol novolaks containing three hydroxyl groups, with methacrylic acid.

Polymethacrylates may be used. A polymethacrylate may be a polyfunctional urethane methacrylate. Urethane methacrylates may be prepared by, e.g., reacting a hydroxyl-terminated polyurethane with methacrylic acid, or by reacting an isocyanate-terminated prepolymer with hydroxyalkyl methacrylates to give the urethane methacrylate. Preferred are urethane methacrylates made from polyester diols, aliphatic isocyanates and hydroxyalkyl methacrylates. Also preferred are those having polyfunctionality of methacrylates or mixed acrylic and methacrylic functionality.

Examples of preferred aliphatic urethane methacrylates used in resins according to the invention include Genomer® 4205, Genomer® 4256 and Genomer® 4297.

Furthermore, higher functionality methacrylates, including hyberbranched polyester types, may also be used for resin modification.

(C) Photoinitiators

According to the present invention, the resin composition comprises at least a photo initiator. The photo initiator can be a photo initiating system comprising a combination of different photo initiators and/or sensitizers. The photo initiating system can, however, be also a system comprising a combination of different compounds, which do not exhibit any photo initiating property when taken alone, but which do exhibit photo initiating properties when combined together.

The photo initiator may be chosen from those commonly used to initiate radical photo polymerization.

Examples of free radical photo initiators include benzoins, e.g., benzoin, benzoin ethers such as benzoin methyl ether, benzoin ethyl ether, benzoin isopropyl ether, benzoin phenyl ether, and benzoin acetate; acetophenones, e.g., acetophenone, 2,2-dimethoxyacetophenone, and 1,1-dichloroacetophenone; benzil ketals, e.g., benzil dimethylketal and benzil diethyl ketal; anthraquinones, e.g., 2-methylanthraquinone, 2-ethylanthraquinone, 2-tertbutylanthraquinone, 1-chloro-anthraquinone and 2-amylanthraquinone; triphenylphosphine; benzoylphosphine oxides, e.g., 2,4,6-trimethylbenzoy-diphenylphosphine oxide (Lucirin® TPO); bisacylphosphine oxides; benzophenones, e.g., benzophenone and 4,4′-bis(N,N′-di-methylamino)benzophenone; thioxanthones and xanthones; acridine derivatives; phenazine derivatives; quinoxaline derivatives; 1-phenyl-1,2-propanedione 2-O-benzoyl oxime; 4-(2-hydroxyethoxy)phenyl-(2-propyl)ketone (Irgacure 2959; Ciba Specialty Chemicals); 1-aminophenyl ketones or 1-hydroxy phenyl ketones, e.g., 1-hydroxycyclohexyl phenyl ketone, 2-hydroxyisopropyl phenyl ketone, phenyl 1-hydroxyisopropyl ketone, and 4-isopropylphenyl hydroxyisopropyl ketone.

For this application, the radical photo initiators are preferably selected and their concentrations are preferably adjusted to achieve an absorption capacity such that the depth of cure is from about 0.05 to about 2.5 mm.

(D) Thiols

According to a preferred embodiment of the present invention, the resin composition comprises at least a monofunctional or multifunctional thiol. Multifunctional thiol means a thiol with two or more thiol groups. A multifunctional thiol may be a mixture of different multifunctional thiols.

The multifunctional thiol component of the inventive compositions may be any compound having two or more thiol groups per molecule. Suitable multifunctional thiols are described in U.S. Pat. No. 3,661,744 at Col. 8, line 76-Col. 9, line 46; in U.S. Pat. No. 4,119,617, Col. 7, lines 40-57; U.S. Pat. Nos. 3,445,419; and 4,289,867. Especially preferred are multifunctional thiols obtained by esterification of a polyol with an .alpha. or β-mercaptocarboxylic acid such as thioglycolic acid, or β-mercaptopropionic acid.

Examples of preferred thiols used in compositions according to the present invention include pentaerythritol tetra-(3-mercaptopropionate) (PETMP), pentaerythritol tetrakis(3-mercaptobutylate) (PETMB), trimethylolpropane tri-(3-mercaptopropionate) (TMPMP), glycol di-(3-mercaptopropionate) (GDMP), pentaerythritol tetramercaptoacetate (PETMA), trimethylolpropane trimercaptoacetate (TMPMA), glycol dimercaptoacetate (GDMA), ethoxylated trimethylpropane tri(3-mercapto-propionate) 700 (ETTMP 700), ethoxylated trimethylpropane tri(3-mercapto-propionate) 1300 (ETTMP 1300), propylene glycol 3-mercaptopropionate 800 (PPGMP 800), propylene glycol 3-mercaptopropionate 2200 (PPGMP 2200).

The number ratio of the methacrylate and acrylate components (containing ene groups) to the multifunctional thiol component can be varied widely. Generally it is preferred that the ratio of ene to thio groups be from 10:1 to 2:1, e.g. 9:1 to 4:1, for example 8:1 to 5:1, but ratios outside this range may occasionally be usefully employed without departing from the invention hereof.

While a curable composition using compounds of the invention may include both difunctional methacrylate and acrylate compounds and difunctional thiol compounds, it will be understood that at least a portion of at least one of these components should contain preferably more than two functional groups per molecule to produce a cross linked product when cured. That is, the total of the average number of ene groups per molecule of methacrylate and acrylate components and the average number of co-reactive thiol groups per molecule of the multifunctional thiol should be greater than 4 when a cross linked cured product is desired.

(E) Stabilizer

PATENT

According to a preferred embodiment of the present invention, the resin composition may comprise a stabilizer or inhibitor, i.e. a compound which is added to the composition to avoid that the composition reacts before being exposed to the applied UV radiation.

A preferred stabilizer is a N-nitroso hydroxyl amine complex with the general structure:

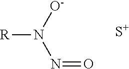

whereby R is an hydrocarbon aromatic rest and S⁺ is a salt.

The N-nitroso hydroxyl amine complex can be an aluminium salt complex, for example with the structure:

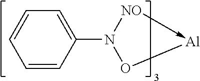

The resin composition according to the invention may comprise nanofillers, for example nanoalumina (Nanobyk 3600, 3601, 3602) or nanosilica particles (Nanocryl, Nanoresins) or any other nanofiller, in order to improve the resolution of the produced 3-dimensional object.

The resin composition according to the invention may also comprise dyes and/or brightening agents.

### FIGURES

Specific inventive embodiments and examples of the apparatus of the system according to the present invention will now be described more in detail with reference to the figures of which

FIG. 1 illustrates a simplified cross-sectional view of a stereo lithography apparatus,

FIG. 2 illustrates a part of the exposure system according to an embodiment of the invention,

FIG. 3 illustrates a cross-sectional view of part of a stereo lithography apparatus comprising a collision-preventing detection system according to an embodiment of the invention,

FIG. 4 corresponds to FIG. 3 rotated 90°,

FIG. 5 illustrates a collision-preventing detection system according to an embodiment of the invention,

FIG. 6 illustrates a protective window according to an embodiment of the invention,

FIG. 7 illustrates a replaceable module comprising a protective window according to an embodiment of the invention,

FIG. 8 illustrates a cross-sectional view of part of a stereo lithography apparatus comprising a replaceable module according to an embodiment of the invention,

FIG. 9 illustrates an example of a stereo lithography apparatus according to an embodiment of the invention,

FIG. 10 illustrates a further example of a stereo lithography apparatus according to an embodiment of the invention,

FIG. 11 illustrates a further example of a stereo lithography apparatus according to an embodiment of the invention,

FIG. 12 illustrates a H-Bench measurement apparatus for differential shrinkage, and the dimensions of the H-bench.

### EMBODIMENTS AND EXAMPLES

System

Examples of a method and an illumination unit for point illumination of a medium explaining how to collimate light and illuminate suitable to embodiments of the present invention can be seen e.g. in WO 98/47048, hereby incorporated by reference.

Examples of an illumination unit and a method of point illumination of a medium comprising a plurality of light emitters in the form of light guides which are arranged to illuminate at least one illumination face via a light valve arrangement suitable to embodiments of the present invention can be found e.g. in WO 98/47042, hereby incorporated by reference.

An example of a rapid prototyping apparatus for the manufacturing of three-dimensional objects by additive treatment of cross-sections comprising a wholly or partially light-sensitive material is described in WO 00/21735, hereby incorporated by reference. This apparatus comprises at least one light source for illumination of a cross-section of the light-sensitive material by at least one spatial light modulator of individually controllable light modulators, wherein at least one light source is optically coupled with a plurality of light guides arranged with respect to the spatial light modulator arrangement in such a manner that each light guide illuminates a sub-area of the cross-section.

Within the context of this description and the appended claims, with the term “illumination area” is meant an approximated plane as defined by a number of focus points of the individual light beams originating from the output optics.

Within the context of this description and the appended claims, with the term micro-lenses is meant small lenses, generally with diameters less than one millimetre (mm).

Within the context of this description and the appended claims, with the term focusing distance d is meant the minimum distance from the output optics to the illumination area.

Within the context of this description and the appended claims, with the term light-sensitive material is meant a material sensitive to light and suitable for three-dimensional rapid prototyping. Such material will be well-known to the skilled person and could advantageously be different kinds of resin; hence the term resin, resin composition and the term light-sensitive material are used interchangeably herein.

Within the context of this description and the appended claims, with the term Illumination Area is meant the cross-sectional area of the light beam at the distance, where the light beam is best focused.

Within the context of this description and the appended claims, a pattern of light can be caused by any combination of the light modulators, e.g. when all light modulators are open, a single line of light modulators are open, some individual light modulators are open or any other combination of settings of the light modulators.

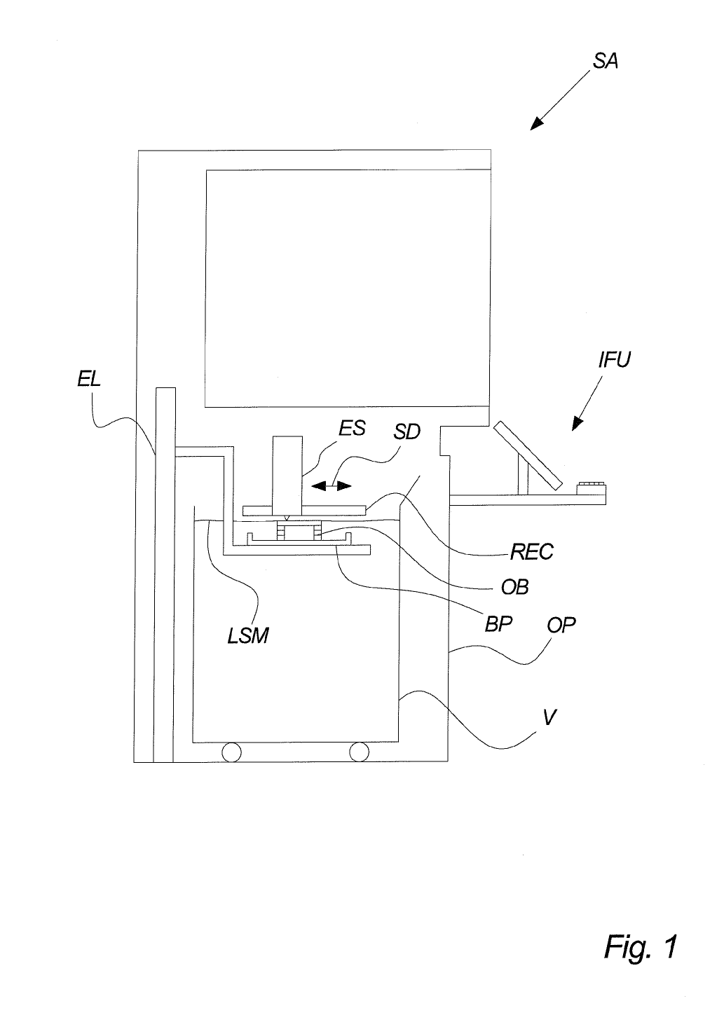

FIG. 1 illustrates a simplified cross-sectional view of a stereo lithography apparatus SA for building three-dimensional objects OB according to one aspect of the present invention. The three-dimensional objects OB are built layer-wise through the curing of light sensitive material LSM when exposed to light from the exposure system ES.

The stereo lithography apparatus SA comprises a building plate BP, on which one or more three-dimensional objects OB is built. The building plate BP is moved vertically into a vat V comprising light-sensitive material LSM by means of an elevator EL. A recoater REC is according to an aspect of the invention scanned across the new layer of light-sensitive material LSM to ensure uniformity of the new layer. The scanning direction SD of the exposure system ES is indicated with arrows.

According to the above description the three-dimensional object OB is built by exposing a layer of light-sensitive material LSM with patterned light from the exposure system ES. The part of the light-sensitive material LSM is cured according to the pattern of light to which it is exposed. When a first layer is cured, the building plate BP with the cured first layer of the three dimensional object OB is lowered into the vat V and the recoater REC scans across the layer of light-sensitive material LSM in order to establish a fresh upper layer of light-sensitive material LSM. Then the exposure system ES is again scanned across the light-sensitive material LSM curing a new layer of the three-dimensional object OB.

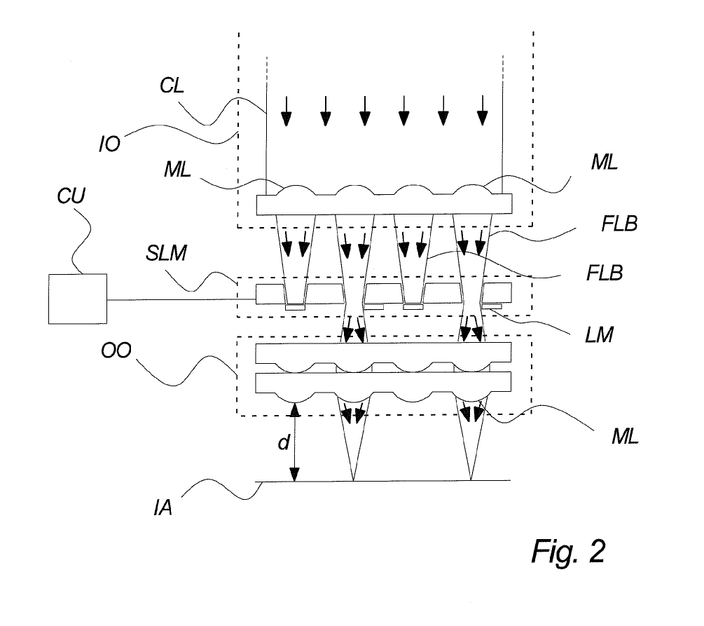

As mentioned, the stereo lithography apparatus SA comprises an exposure system ES. The exposure system ES comprises an incoherent illumination source, which may be a UV-lamp, a diode, a number of diodes, or any other means of illumination source known by the skilled person suitable for the purpose of curing the light-sensitive material. Following the illumination source there are means for transforming the light from the illumination source into collimated light together with input optics IO, spatial light modulators SLM, and output optics OO. The part of the exposure system following the means of collimating the light is depicted on FIG. 2.

At least part of the exposure system ES is scanned across the light-sensitive material LSM in a scanning direction SD, illuminating an illumination area IA on the surface of the light-sensitive material LSM according to a digital layer-wise representation of the three-dimensional object OB. According to an aspect of the invention, the exposure system ES is curing the light-sensitive material LSM in the illumination area IA, thereby forming the three-dimensional object OB.

In an aspect of the invention, the vat V may be equipped with means for moving the vat V such as wheels, interactions with a rail, track, forklifts etc. Hence the vat V may be removable located in the stereo lithography apparatus SA e.g. accessible via an opening OP to refill the vat V with light-sensitive material LSM or to easy removal of three-dimensional objects OB from the building plate BP.

It should be noted that it is possible, e.g. by means of the illustrated elevator EL or other devices, to move the vat V vertically instead of moving the building plate BP.

The digital layer-wise representation of the three-dimensional object OB may, according to an aspect of the invention, be provided to the stereo lithography apparatus SA via an interface unit IFU. The interface unit IFU may comprise input interfaces, such as e.g. a keyboard or pointer and output interfaces such as e.g. a screen or a printer, to handle communication via interfaces such as e.g. LAN (LAN; Local Area Network), WLAN (WLAN; Wireless Local Area Network), serial communication etc. Furthermore the interface unit IFU may comprise data processors, memory's and/or means for permanent storing of data.

FIG. 2 illustrates a simplified cross-sectional view of the part of the exposure system following the means of collimating the light according to an aspect of the invention.

According to one aspect of the invention, in order to transmit light from the illumination source to at least part of the light modulators LM of the at least one spatial light modulator SLM, light guides are used between the means for collimation and the input optics IO. In another aspect of the invention, which may be combined with the other, light guides are used between the illumination source and the means for collimation. Such light guides may e.g. comprise optical fibres (e.g. made of polymer, plastic, glass etc.), optics, lens arrays, reflectors, etc.

According to an aspect of the invention the light-sensitive material LSM may be a determining factor for the choice of illumination source. Typically the light-sensitive material LSM is cured when exposed or illuminated with light of high intensity within wavelengths between 200-500 nm. Typically light with a wavelength peaks between 300 and 400 nm are the most optimal for curing the preferred type of light-sensitive material LSM. Of course, light with other than the mentioned wavelengths may be used if a special light-sensitive material LSM is required. Since the illumination source is incoherent, the light is emitted with a broad wavelength range and several chemical compounds and photo initiators can be activated in the light-sensitive material.

It should be noted that the light-sensitive material LSM is also cured when it is exposed to a broad-spectrum light e.g. from the diffuse illumination distribution of a room, because the diffuse illumination distribution of a room often also contains light with wavelengths on which the light-sensitive material LSM reacts. Curing of light-sensitive material LSM from such stray light is not desirable because it is slow and not controllable.

The intensity of the light emitted from the illumination source may according to an aspect of the invention vary. The higher the intensity, the shorter the time the light-sensitive material LSM has to be exposed to the light to cure. Hereby the speed of the exposure system ES scanning over the light-sensitive material LSM may be faster. Of course other factors are also determining for the scanning speed such as the type of light-sensitive material LSM, response time in the spatial light modulators SLM, etc.

According to an aspect of the invention, the exposure system comprises input optics IO, at least one spatial light modulator SLM and output optics OO. Hence light from the illumination source are, by means of the input optics IO, at least partly collimated and focused onto at least some of the apertures of the at least one spatial light modulator SLM. The at least one spatial light modulator SLM then establishes a pattern of light onto the output optics OO, which again focuses the patterned light on the illumination area IA on the light-sensitive material LSM.

It should be noted that a pattern of light also includes the situation when all individual light modulators LM of the spatial light modulator SLM are in a position which either let's light through all apertures of the spatial light modulator SLM or does not let any light at all through the apertures of the spatial light modulator SLM.

According to a preferred aspect of the invention the stereo lithography apparatus SA comprises more than 48 spatial light modulators SLM. It should be noted that the stereo lithography apparatus SA may be very flexible in relation to the number of spatial light modulators SLM. Hence the number of spatial light modulators SLM may vary between 1 and e.g. up to more than 100.

According to an aspect of the invention, the individual spatial light modulators SLM may be combined in modules of four. Hence, according to a preferred aspect of the invention, when more than four spatial light modulators SLM are needed, more than one module are combined together forming the exposure system ES.

Each spatial light modulator SLM comprises according to an aspect of the invention more than 500 individually controllable light modulators LM. Of course, spatial light modulators SLM with a number which differs from the 500 individually controllable light modulators LM may be used. To simplify the figures, throughout this description the figures only illustrate the spatial light modulators SLM with e.g. four light modulators even though, as mentioned, there may be more than 500.

The input optics IO may according to an aspect of the invention and as shown in FIG. 2 comprise a micro lens array. In further embodiments further micro lenses may be included in the input optics as well as other optical elements.

A purpose of the input optics is to focus the collimated light CL onto the at least one spatial light modulator SLM. As explained below, the at least one spatial light modulator SLM comprises a plurality of apertures and it is onto or down through these apertures that the micro lenses ML are focusing the collimated light CL.

The at least one spatial light modulator SLM may according to an aspect of the invention be used to pattern the collimated and focused light onto illumination areas IA on the light sensitive material LSM. The at least one spatial light modulator SLM comprises a plurality of individual light modulators LM also referred to as light switches, light valves, micro shutters etc.

According to an aspect of the invention, the individual controllable light modulators LM are controlled by a control unit CU. The control unit CU may control the exposure system ES according to the digital layer-wise representation of the three-dimensional object to be built. The illustrated control unit CU may control the individual controllable light modulators LM of the at least one spatial light modulator SLM and in the case of individual light-emitting diodes LD, these may also be controlled by the control unit CU.

According to an aspect of the invention where light-emitting diodes LD are used, controlling the light-emitting diodes LD means to turn the light-emitting diodes LD off if e.g. only a small part of an object or a small object is to be built, which does not require patterned light from at least one spatial light modulator SLM included in the exposure system ES.

According to an aspect of the invention, the control of the light modulators LM in the at least one spatial light modulators SLM may be done by addressing the light modulators LM according to the pattern. The pattern may represent one layer of the three dimensional object to be built.

In an embodiment of the invention, the illustrated control unit CU may also control other parts of the stereo lithography apparatus SA than the exposure system ES. Alternatively, the control unit CU may be included in other control systems in relation to the stereo lithography apparatus SA.

According to an aspect of the invention the stereo lithography apparatus SA may be provided with digital layer-wise descriptions of the three-dimensional object to be built. The layer-wise description of the three-dimensional object may include support structure, if the three-dimensional object requires support during the building process. For each layer of the three-dimensional object, the exposure system ES is scanned across the light-sensitive material LSM and the individual digital layer-wise description of the three-dimensional object determines the pattern of light from the spatial light modulator SLM.

According to an aspect of the invention the output optics OO focuses the patterned light from the spatial light modulator SLM onto one or more illumination areas IA on the surface of the light-sensitive material LSM. Like the input optics IO, the output optics OO may comprise more than one lens system e.g. more than one array of micro lenses ML.

A preferred embodiment of part of an exposure system is shown in FIG. 2. Collimated light CL is sent through a first micro lens array as part of the input optics IO, which works to focus the collimated light CL into a number of focused light beams FLB suitable for entering each individual shutter on the light modulators LM.

For each open light modulator LM the light will go through and spread out again after having travelled through the light modulator LM. In this shown embodiment, the output optics OO comprises two micro-lens arrays in immediate continuation of one another to focus the light, whereby desired light spots of a diameter of approximately 100 μm are obtained on a focal plane, the illumination area IA, at a distance d of approximately 2-3mm.

In the shown embodiment this highly advantageous focusing of the light in the desired distance has been obtained by using the above-mentioned two micro-lens arrays in immediate continuation to one another with suitable parameters, namely a curvature radius of 365 μm and a back focal length of 499 μm. Together with the use of a single micro-lens array in the input optics with a curvature radius of 328.5 μm and a back focal length of 425 μm, this combination has proven to provide a highly advantageous combination of optics in the exposure system. However, further optical elements with values of these parameters in a range around such found values have also shown to provide advantageous results.

In this embodiment the used micro-lenses are part of an array comprising a number of lenses manufactured in one piece. Obviously within the scope of the invention, it would be possible to manufacture and insert individual lenses for each individual shutter, or any number of lenses other than the one shown may be combined together on one micro lens plate.

It should be clear that the embodiment shown in FIG. 2 is shown solely as an example and suitable embodiments may be obtained by replacing one or more of the micro-lens arrays.

Back focal length and curvature radius are terms well-known to the skilled person. However for sake of clarity these are defined as follows.

A spherical lens has a centre of curvature located in (x, y, z) either along or decentred from the system local optical axis. The vertex of the lens surface is located on the local optical axis. The distance from the vertex to the centre of curvature is the curvature radius of the lens.

Back focal length (BFL) is the distance from the vertex of the last optical surface of the system to the rear focal point.

According to the present invention contamination of the exposure system may be prevented or at least kept at a minimum level by the use of one or more protective windows.

FIG. 6 shows an example of a protective window PW according to an embodiment of the invention.

FIG. 7 shows an example of a replaceable module RM according to an embodiment of the invention. The shown replaceable module RM comprises 16 protective windows PW; however this number may be any other suitable number. In the shown embodiment the individual protective windows PW are mutually displaced to cover the full width of the scanning area. Obviously these protective windows PW may be differently distributed depending on different parameters such as the size of the scanning area etc.

FIG. 8 shows an exposure system ES, on which a replaceable module RM comprising a protective windows PW is mounted in fastening means FM for holding the replaceable module RM. In the shown embodiment these fastening means FM are simply rails on each side of the exposure system ES.

In another advantageous embodiment the fastening means FM is a system where the replaceable module RM can be pushed into a recess and then snapped into a fixed position.

However, a number of different suitable fastening means will be apparent for the skilled person.

A protrusion PR is shown in FIG. 8, which in the depicted case may be a bubble in the upper surface US of the resin LSM. Such a bubble is an example of a protrusion PR, which for most resin types will seldom occur. However, if it turns up, this may happen quite suddenly, whereby a possible detection system mounted elsewhere on the apparatus, although effective, might not be sufficient.

With the protective window(s) PW such a bubble may leave small amounts of resin on the protective window(s), but the optics is left undamaged and uncontaminated. Hereby the relatively simple process of replacing the replaceable module RM is sufficient for being able to restart the apparatus following the occurrence of such a bubble.

Another example of a cause of a protrusion is that the curing of the resin may produce a little shrinkage. Such shrinkage may cause that uncured resin LSM surrounding the cured area is pushed up slightly above the level of the surrounding resin. In this way such resin may be brought closer to or even into contact with the exposure system ES.

According to the present invention a sensor may be used to detect obstacles between an exposure system and the resin in additive manufacturing, in order to prevent contamination of the exposure system and to prevent damages on the built part.

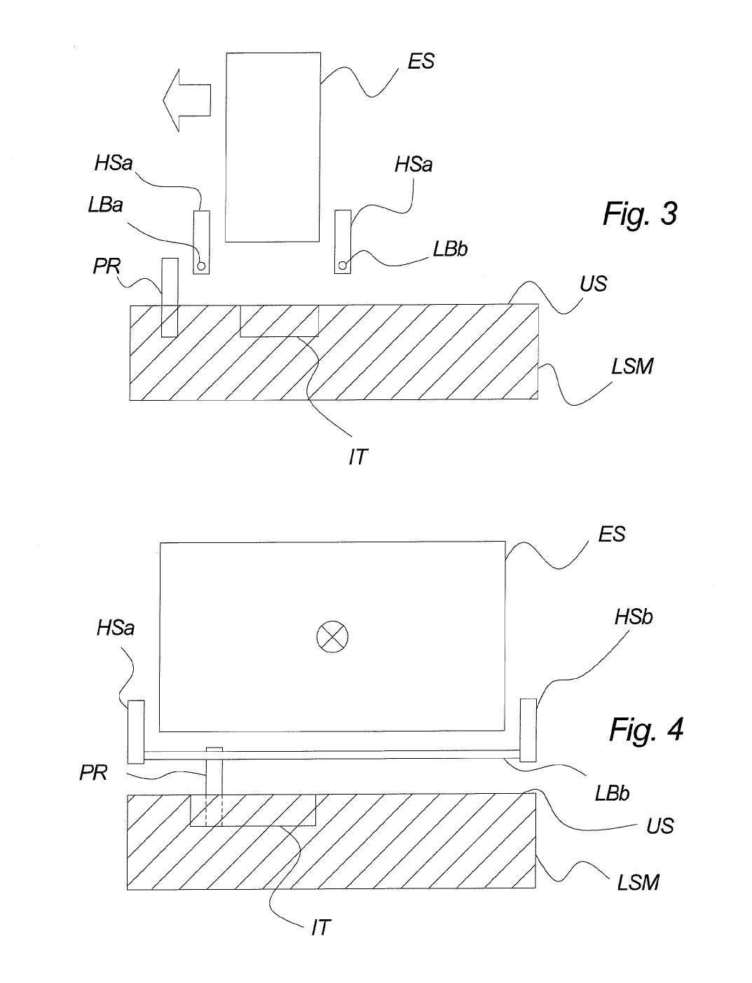

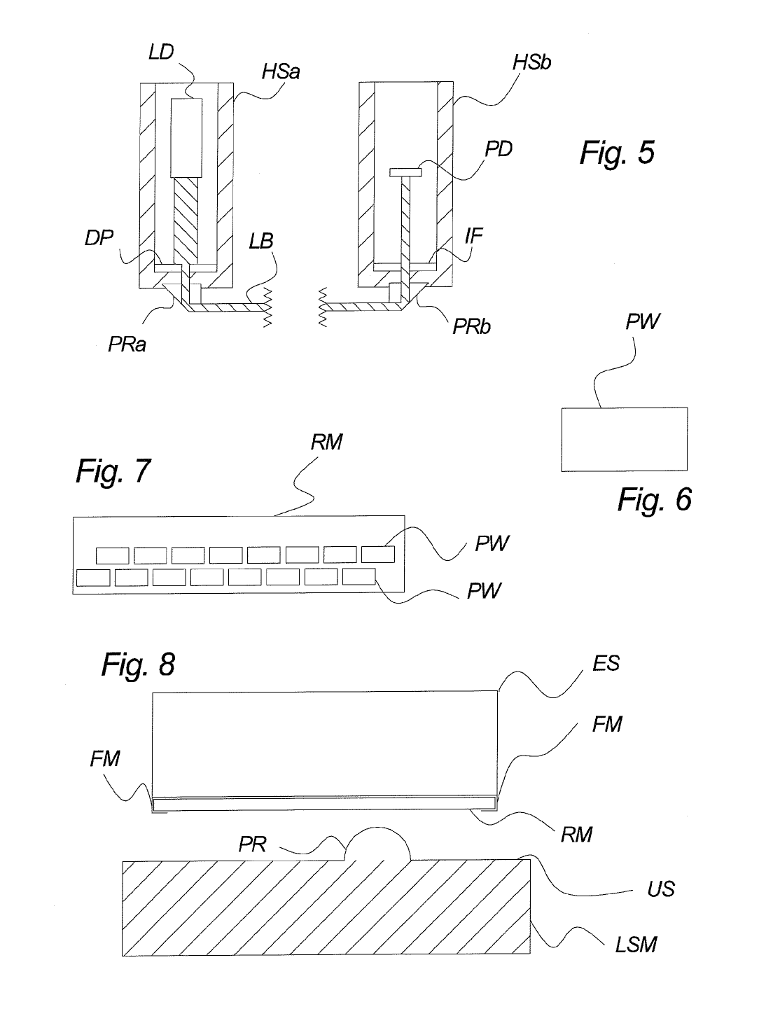

FIG. 3 shows the main parts of the exposure system ES with the exposure system ES moving to the left towards a protrusion PR protruding from the otherwise planar surface of the vat V containing light-sensitive material LSM. In the vat V it is moreover shown a part of an item IT maintaining its upper surface as intended, namely essentially flush with the upper surface US of the light-sensitive material LSM. In the shown embodiment the collision-preventing detection system comprises two laser beams LBa and LBb emitted from housings HSa, which is described more in detail with reference to FIG. 5. It is noted that in the shown embodiment two laser beams LBa and LBb are positioned on the sides of the exposure system ES, in order to be able to detect protrusions, no-matter whether the exposure system ES moves to the left or to the right in the shown embodiment. However, in further embodiments of the invention, only one laser beam may be used or even more than two.

FIG. 4 shows the same setting as in FIG. 3 in a 90° rotated view, i.e. the exposure system ES moves away from the viewer towards the protrusion PR. Hereby one of the laser beams LBb can be seen extending below the whole width of the exposure system ES from a light-emitting housing HSa to a light-sensing housing HSb. Is it noted that the shown laser beam will be the one to the rear of the moving direction, whereas the one in the front of the moving direction cannot be seen in the figure as it is positioned behind the rear laser beam also drawn in FIG. 3.

From the figure it can be seen that the front laser beam LBa, positioned in the figure behind the laser beam LBb, will reach the protrusion PR at some stage during the movement and thereby the laser beam LBa will be interrupted by the protrusion PR resulting in a decreased light intensity reaching the light sensing housing HSb. Hereby it can be concluded that a protrusion PR is present in front of the exposure system ES, which may be a risk for contamination of the exposure system. A signal can be then sent resulting for instance in a stop of the apparatus so that operation staff can solve the problem. In this way the protrusion may be easily removed or lowered and the apparatus may be started again maybe a few minutes later. In case the protrusion PR gets into contact with the exposure system ES a cleaning or replacing process may be necessary resulting in extensive time consumption and costs.

Important elements to make the invention work are the size of the parts in the sensor. As the distance between the bottom surface of the exposure system and the surface of the resin typically is as small as 2 mm, the parts that produce the light beam must be small and made with small tolerances. If the width of the scanning bar as an example is 670 mm, this will also set a lower limit for the distance between emitter and sensor, which will typically be just above this value. Assuming that half the distance between the bottom surface of the exposure system and the resin can be acceptable for the angular misalignment, the angular misalignment must be less than 0.08°. Assuming that half of the distance between the bottom surface of the exposure system and the resin surface can be used for the diameter of the beam, the beam size must be less than 1 mm. Hereby it may be avoided that the receiver will see two sources, one real source from the emitter and one reflection from the resin surface. This illustrates the requirements for the optical parts in the emitter and the sensor and also the requirement to the means used for the micro adjustment of the alignment.

FIG. 5 gives an example of the design of the optical parts, where the two different housings HSa and HSb are shown. Typically the front and the rear set will be the same, hence only one set is shown here.

In this example a laser diode LD emits a laser beam LB which is shaped through a diaphragm DP before it is reflected in a prism PRa through a 90° angle, whereby the beam is directed to be flush just above the surface of the resin. After travelling above the surface US of the resin LSM below the exposure system ES, the beam LB is reflected in a second prism PRb and directed into the light-sensing housing HSb. Before reaching the photo diode PD in this housing, the light beam LB goes through an interference filter IF to avoid that e.g. stray light interferes with the measurement of the photo diode PD.

The use of prisms PRa and PRb is aimed at obtaining a compact design and at avoiding that either the laser diode LD or the photo diode PD need be close to the surface US of the resin LSM. Obviously, angles other than 90° may also be used within the scope of the present invention.

A prism can be used both as an internal or an external reflector; in the embodiment shown in FIG. 5 the prisms are used as internal reflectors. An advantage of using prisms as internal reflectors is that the surfaces of the prism can be made flush with the housing and thus give better cleaning possibilities. To protect the fragile edge of the prism, the edge may simply be cut off as shown in FIG. 5, which allows for the use of clipped beams, whereby parts of the light beam hitting the part cut off will not be essentially bent; this will not produce any risk of stray light beams from the laser between the emitter and the sensor with a risk of impacting the resin. Hereby, without risk of disturbing stray light, the light beam may be moved as close as possible to the surface of the resin, i.e. to the right in FIG. 5. This method may also be used in the external reflection embodiment.

In an advantageous embodiment of the invention the apparatus comprises a restart-button, whereby the apparatus upon an interruption of the laser beam LBa resulting in a stoppage of the apparatus can quickly continue the manufacturing process. This is e.g. advantageous if the interruption was caused by a bubble in the resin or the like, whereby the problem may be solved by the intervention of an operator to the machine.

In an advantageous embodiment of the invention the exposure system comprises modules of spatial light modulators (SLM), wherein each module comprises more than one spatial light modulator.

In an advantageous embodiment of the invention the input optics is made of modules, hence one input optics module corresponds to one module of spatial light modulators.

In an advantageous embodiment of the invention the output optics is made of modules, hence one output optics module corresponds to one module of spatial light modulators. The modular structure of the exposure system, the input optics and the output optics facilitates easy modification of the exposure system e.g. to meet specific user defined requests for the size of the illuminations system.

In an advantageous embodiment of the invention the input and output optics are made of modules, hence one input and one output optic module corresponds to one spatial light modulator.

In an advantageous embodiment of the invention the light modulators of the spatial light modulator pattern the light from the illumination source. The light-sensitive material is cured in a pattern in dependence on the position of the light modulators in the spatial light modulator.

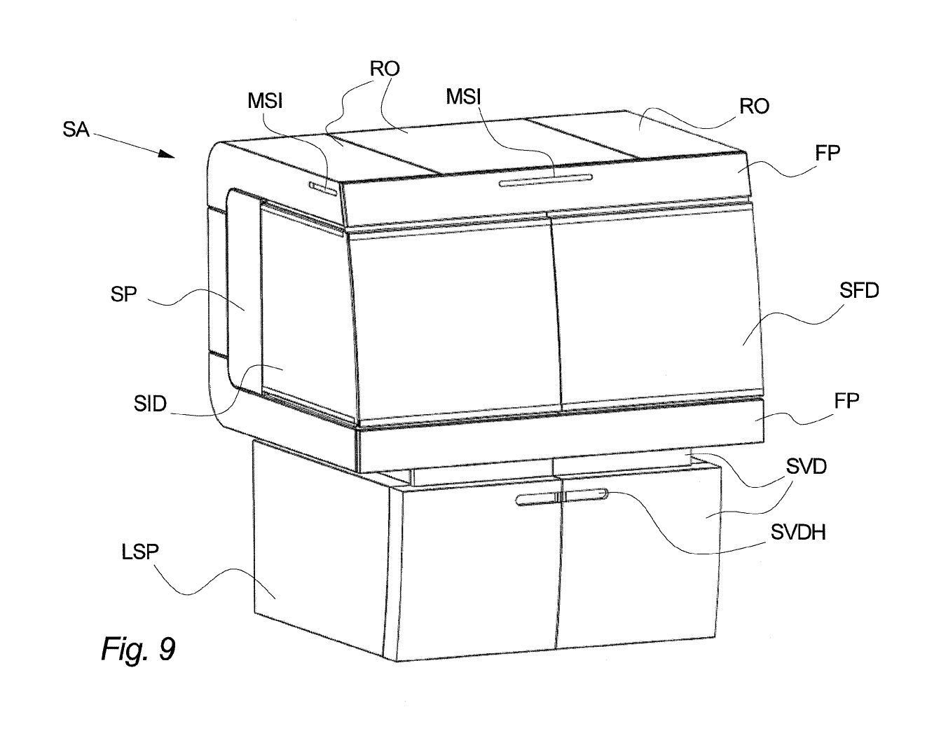

FIG. 9-11 illustrates only one possible embodiment of the stereo lithography apparatus SA. It should be noted that not all below mentioned features are necessary for the stereo lithography apparatus SA to operate. Furthermore, it should be noted that not all details of the stereo lithography apparatus SA are illustrated and that additional, not illustrated, parts may be advantageous.

FIG. 9 illustrates the stereo lithography apparatus SA in a front/side view according to an aspect of the invention.

The stereo lithography apparatus SA may be equipped with one or more sliding vat doors SVD, which may e.g. be opened by means of a sliding vat door handle SVDH, which is operated e.g. by pushing, turning, etc. The sliding vat door SVD may give access to the vat V (not shown) by means of sliding to one side or by means of pivoting around one or more hinges.

One or more sliding front doors SFD may be positioned in relation to one or more front panels FP and side panels SP.

The sliding front door SFD may give access to the exposure system ES (not shown) by means of sliding to one side or by means of pivoting around one or more hinges. It should be noted that the sliding front doors SFD may be transparent so that the building process can be monitored without opening the sliding front door SFD.

The one or more front panels FP may extend to the side of the stereo lithography apparatus SA. The one or more front panels FP may be equipped with one or more machine status indicators MSI, indicating the status (e.g. in operation, stopped, fault, etc.) of the machine or at which stage of a building process the stereo lithography apparatus SA is at a given time. The machine status indicator MSI may also be located on the roof RO or side of the stereo lithography apparatus SA and it may e.g. comprise a display, lamps, sirens etc.

Furthermore the stereo lithography apparatus SA may be equipped with one or more side doors SID and one or more lower side panel LSP, which are not in use under normal operation of the stereo lithography apparatus SA. The side doors SID and the lower side panel LSP are only dismounted or opened when parts of the stereo lithography apparatus SA must be maintained.

It should be noted that the side doors SID may according to an aspect of the invention be part of the sliding front door SFD and the lower side panel LSP may according to an aspect of the invention be part of the sliding vat door SVD.

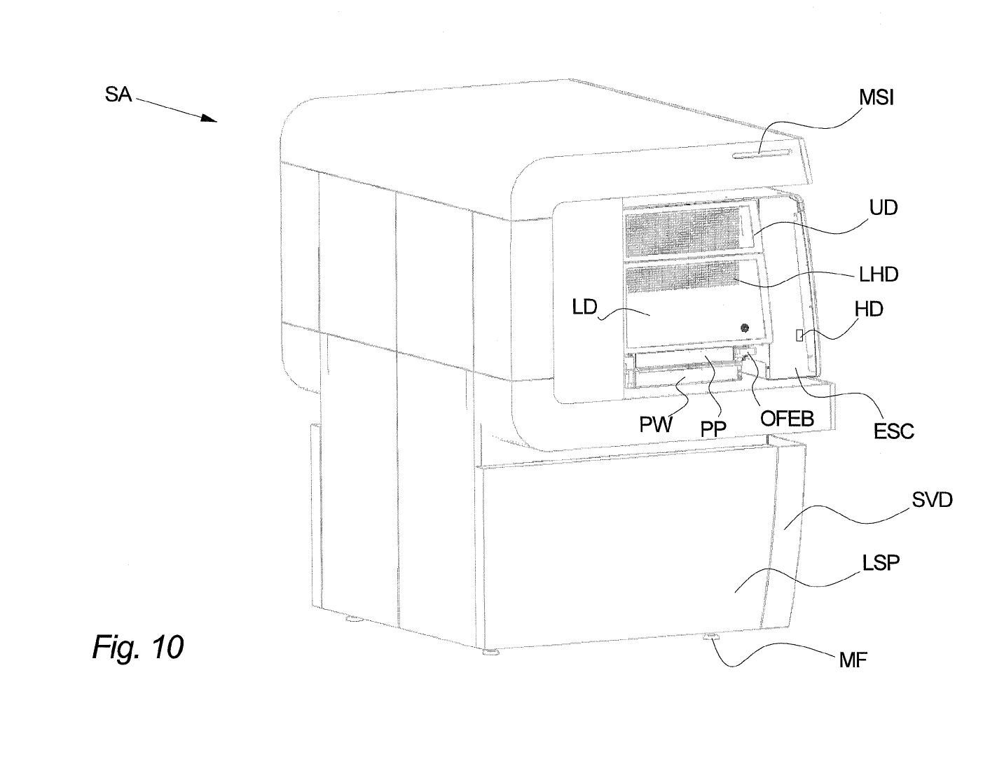

FIG. 10 illustrates the stereo lithography apparatus SA in a back/side view according to an aspect of the invention, where the side door SID and the sliding front door SFD are dismounted, revealing the exposure system ES.

The stereo lithography apparatus SA may according to an aspect of the invention stand on one or more machine feet MF, which may be adjustable. This may make easier installing the stereo lithography apparatus SA, so that when the vat V (not shown) is located into the stereo lithography apparatus SA the surface of the light-sensitive material LSM and the output optics OP (not shown) are substantially parallel.

The illustrated exposure system ES comprises an upper left side door UD and a lower left side door LD used when maintaining or servicing the exposure system ES. Furthermore, the exposure system comprises a lamp housing door LHD for accessing the illumination source IS (not shown). Furthermore, the exposure system ES comprises a protection plate PP for protecting the different parts of the illumination unit IU (not shown). The side of the protection window PW is also illustrated on FIG. 10 together with the outer frame of the exposure bar OFEB

A handle HD for releasing the protection window PW (not shown) may be located in the exposure system casing ESC.

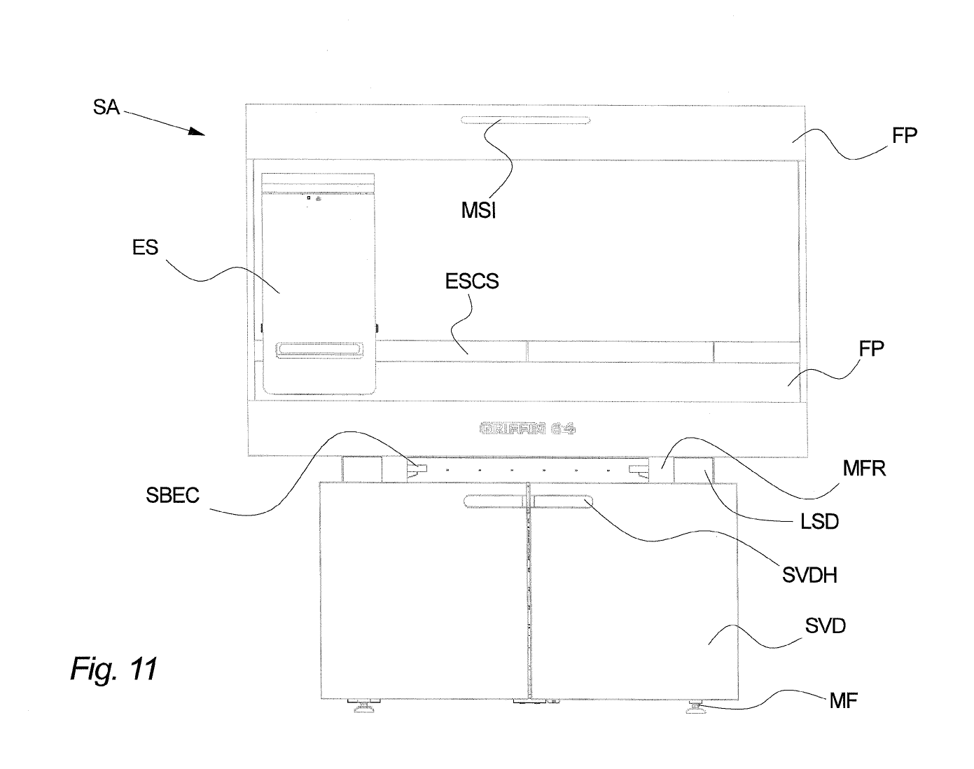

FIG. 11 illustrates the stereo lithography apparatus SA in a front view according to an aspect of the invention, where the sliding front door SFD is removed. The exposure system ES is moving in a exposure system carriage slit ESCS, when scanning across the light-sensitive material LSM (not shown). Furthermore FIG. 11 illustrates the machine frame MFR around which the machine is build and a support base for the exposure system energy chain SBEC.

In the stereo lithography apparatus SA described above the light-sensitive material LSM is illuminated by a low intensity incoherent collimated light CL focused into a number of focused light beams FLB suitable for entering each individual shutter on the light modulators LM. Desired light spots of a diameter of approximately 100 μm are obtained on a focal plane, the illumination area IA, where the upper surface US of the light-sensitive-material LSM is situated.

Acrylate or methacrylate based resin compositions must be therefore used as the light-sensitive material in the system, since acrylate or methacrylate compounds can be cured even by low intensity incoherent light.

Resin compositions with low viscosity are preferred in the apparatus disclosed above, since such compositions allow a fast recoating process to be carried out.

Resin Composition

Composition Preparation

Examples of resin compositions according to the present invention are disclosed in the following. Table 1 a shows the trade names, suppliers and chemical names of the compounds used in said examples.

TABLE 1 a

| Trade Name | Supplier | Chemical Name |
|---|---|---|
| Sartomer ® 349 | Cray Valley/ | 2-Propenoic acid, α,α′-[(1-methylethylidene)di-1,4- |
| | Sartomer | phenylene]bis[ω-hydroxypoly(oxy-1,2-ethanediy1)] ester |
| Sartomer ® 833s | Cray Valley/ | Octahydro-4,7-methano-1H-indenediyl)bis(methylene) |
| | Sartomer | diacrylate |
| Sartomer ® 344 | Cray Valley/ | Poly(oxy-1,2-ethanediy1), a-(1-oxo-2-propen-1-yl)-ω-[(1- |
| | Sartomer | oxo-2-propen-1-yl)oxy]- |
| Sartomer ® 348C | Cray Valley/ | Poly(oxy-1,2-ethanediy1), a,a′-[(1-methylethylidene)di-4,1- |
| | Sartomer | phenylene]bis[ω-[(2-methyl-1-oxo-2-propen-1-y1)oxy]- |
| Genomer ® 4205 | Rahn AG | Aliphatic Urethane Dimethacrylate |
| Lucian ® TPO | BASF | Diphenyl(2,4,6-trimethylbenzoyl)phosphine oxide |
| Irgacure ® 651 | Ciba | 2,2-Dimethoxy-1,2-diphenylethan-1-one |
| Thiocure ®PETMP | Bruno Bock | Pentaerythritol tetrakis(3-mercaptopropionate) |
| Wako ® Q1301 | Wako Chemicals | Tris(N-hydroxy-N-nitrosophenylaminato-O,O′)aluminium |
| Craynor ® CN 981 | Cray Valley/ | Aliphatic Urethane Diacrylate |
| | Sartomer | |
| Thiocure ® TMPMP | Bruno Bock | Trimethylol-propane Tri-(3-mercapto-propionate) |
| Thiocure ® TMPMA | Bruno Bock | Trimethylolpropane Trimercaptoacetate |
| Thiocure ® GDMA | Bruno Bock | Glycol Dimercapto-acetate |
| Thiocure ® GDMP | Bruno Bock | Glycol Di-(3-mercapto-propionate) |
| Thiocure ® PPGMP 800 | Bruno Bock | Propylene- glycol 3-Mercapto-propionate |
| Thiocure ® ETTMP | Bruno Bock | Ethoxylated Trimethylol-propane Tri(3-mercapto- |
| 1300 | | propionate) |
| Thiocure ® PETMA | Bruno Bock | Pentaerythritol Tetramer-captoacetate |
| Karenz MT ® PE1 | Showa denko | Pentaerythritol tetrakis(3-mercaptobutylate) |
| PETMB | | |

Genomer® 4205 is an aliphatic urethane methacrylate, Sartomer® 348C is an ethoxylated bisphenol A dimethacrylate, Sartomer® 349 is an ethoxylated (3) bisphenol A diacrylate, Sartomer® 833 is a tricyclodecane dimethanol diacrylate, Sartomer® 0344 is a polyethylene glycol diacrylate. The used Thiocure and Karenz compounds are thiols.

Compositions in the examples were prepared by complete dissolution of all solid components into liquid components at 60° C. with stirring. Where a thiol component was involved in a formulation, this was added as the last component with stirring. After dissolution of solid components, and after the formulation was allowed to cool to room temperature

Tables 2-7 shows different examples of resin compositions according to the present invention. A Control composition (Example 1) is represented and also other compositions, whereby Sartomer 833 is varied between 0 and 40% by weight (Examples 2-5, Table 2) or whereby Genomer 4205 is varied between 0 and 40% by weight (Examples 6-9, Table 3) or whereby Sartomer 349 is varied between 0 and 20% by weight (Examples 10-11, Table 4) or whereby Sartomer 344 is varied between 0 and 20% by weight (Examples 12-13, Table 4). In Example 14 (Table 4) Sartomer 348 is present in an amount of 20% by weight. Table 5 (Examples 15-16) and 6 (Examples 17-20) show the influence of the addition of PETMP in concentrations between 0% and 9% by weight. And finally Table 7 (Examples 21-28) shows the influence of various thiols in a concentration of 5% by weight. The viscosity of said resin compositions, the green strength of the objects produced by curing the corresponding resins and the mechanical properties of the three-dimensional objects obtained after post curing have been indicated in Table 2-7 for each resin composition.

Curing/Production of Test Parts

Formulations were cured using the Stereo lithography apparatus SA, with the exposure system described above.

The photo curable composition is placed in a vat designed for use with the Stereo lithography apparatus SA at about 30° C. The surface of the composition, either in its entirety or in accordance with a predetermined pattern, is irradiated with an Ultraviolet/Visible light source so that a layer of desired thickness is cured and solidified in the irradiated area. A new layer of the photo curable composition is formed on the solidified layer. The new layer is likewise irradiated over the entire surface or in a predetermined pattern. The newly solidified layer adheres to the underlying solidified layer. The layer formation step and the irradiation step are repeated until a “green model” of multiple solidified layers is produced.

A “green model” is a three-dimensional article initially formed by the stereo lithography process of layering and photo curing, where typically the layers are not completely cured. This permits successive layers to better adhere by bonding together when further cured. “Green strength” is a general term for mechanical performance properties of a green model, including modulus, strain, strength, hardness, and layer-to-layer adhesion. For example, green strength may be reported by measuring flexural modulus (according to ASTM D 790). An object having low green strength may deform under its own weight, or may sag or collapse during curing.

The green model is then washed in Isopropanol and subsequently dried with compressed air. The dried green model is next postcured with UV radiation in a postcure apparatus (“PCA”) for 60 to 90 minutes. “Postcuring” is the process of reacting a green model to further cure the partially cured layers. A green model may be postcured by exposure to heat, actinic radiation, or both.

Cure of the samples for the mechanical tests in the Stereo lithography apparatus SA was carried out with the scanning bar moving at 10 mm/s (cure speed), in a multicavity vat system, using standard perforated building plates to produce mechanical test parts.

The power flux of the light focused onto the illumination area was around 25 mW/cm². The accumulated exposure time was around 0.68 s. The Stereo lithography apparatus described SA above can, however, delivery power fluxes at the illumination area from 5 mW/cm² to 60 mW/cm².

Parts produced in this way were then washed in isopropanol and finally cured in a Post Cure Apparatus (PCA) for 90 minutes. Mechanical test properties were measured on the post cured parts after conditioning 3-5 days at 23° C. and 50% room humidity.

Viscosity Measurement

The viscosity of the liquid mixtures is determined at 30° C., using a Rheostress RS80 Rheometer.

Mechanical Test Procedures

The mechanical properties of the produced samples have been measured according to the corresponding ISO/ASTM Standards, as listed in Table 1b.

TABLE 1 b

| | ISO/ASTM |
|---|---|
| | standard |
| Tensile properties: elongation to break, strength, modulus | ISO 527 |
| Flexural properties: Maximum strength, modulus | ISO 178 |
| Bend Notched Impact Resistance: | ISO 13586 |
| Fracture toughness (G1C), stress intensity coefficient (K1C) | |
| HDT at 1.8 MPa (or 0.45 MPa): | ISO 75 |
| Heat deflection temperature under 1.80 MPa or 0.45 MPa load | |
| Green Strength (Flexural modulus) | ASTM D790 |

Shrinkage Measurement by H-Bench or Mould Measurement (Volume %)

Volume shrinkage by the mould method is determined by measurement of the length of a mould used to produce parts of 100mm×5mm.×5mm. Measurement of the length of the final cured part and comparison with the length of the mould used to produce the part gives an indication of the linear shrinkage (%), and by calculation, Volume shrinkage (%) of a part (assuming equal shrinkage in all directions). All measurements are made at 23° C./50% relative humidity.

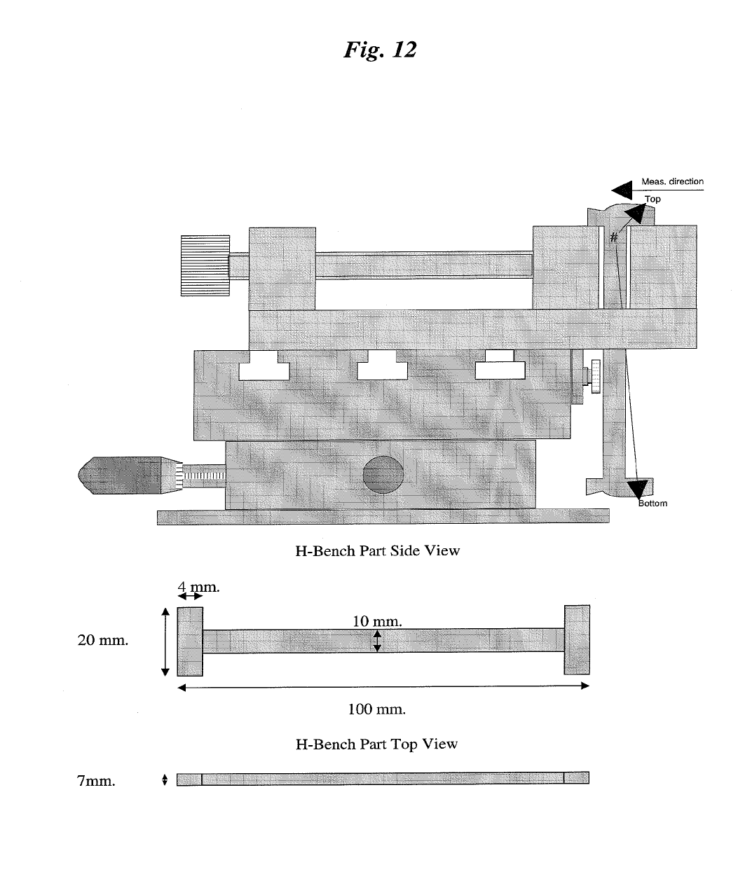

Differential shrinkage by H-Bench measurement is carried out with the equipment depicted in FIG. 12 at 23° C./50% relative humidity.

With reference to FIG. 12, a part is built using the Stereo lithography apparatus SA, which resembles an “H” with an elongated central portion, such that the two vertical parts of the H are built upright in the vertical direction. This part is then held loosely as shown in the apparatus in FIG. 12 and a Focodyn laser profilometer is used to measure the surface profile. Differential shrinkage is the distance in microns between the maximum and minimum points of the measured surface profile. Dimensions of the “H” part are also shown in FIG. 12.

Determination of Photosensitivity (Dp/Ec)

The photosensitivity of the compositions is determined using “stripes” of cured composition. In this determination, single-layer test specimens are produced using the Stereo lithography apparatus SA with different cure speeds, and hence different amounts of energy. The layer thicknesses of these stripes are then measured. The plotting of the resulting layer thickness on a graph against the logarithm of the irradiation energy used gives the so-called “working curve”. The slope of this curve is termed Dp (depth of Penetration, in microns). The energy value at which the curve passes through the x-axis is termed Ec (Critical Exposure Energy, in mJ/cm²). (Cf. P. Jacobs, Rapid Prototyping and Manufacturing, Soc. Of Manufacturing Engineers, 1992, pp 270 ff.)

Results of the Mechanical Tests

In Table 2 we can observe the increase of Sartomer 833 in the composition from 0% to 40% wt. It can be observed in Table 2, that the composition exhibits surprisingly and unexpectedly a maximum of toughness (K1c, G1c, elongation at break) and of tensile strength at a concentration of Sartomer 833 between 5% and 15% wt, which was found to be the optimized concentration range for the cycloaliphatic diacrylate component.

In Table 3 we can observe that the increase of Genomer 4205 in the composition from 0% to 40% wt produces a notable increase in the green strength (from 35 to 65 MPa) and in the flexural strength (from 75 to 85 MPa). Satisfactory mechanical properties can be therefore achieved with a concentration of the aliphatic urethane methacrylate component between 20 and 50% wt.

In Table 4 we can observe that the increase of Sartomer 349 in the composition from 0% to 20% wt produces an increase in the rigidity (tensile modulus, bend modulus, flexural strength) and in the toughness (K1c, G1c). A satisfactory impact strength can be therefore achieved by adding to the composition between 5% and 15% wt of the aromatic diacrylate component.

In Table 4 we can also observe that the increase of Sartomer 344 in the composition from 0% to 20% wt produces a dramatic increase in the flexibility (tensile modulus, bend modulus, flexural strength) and in the toughness (K1c, G1c) and a dramatic decrease in the viscosity. We found that an optimal concentration of the polyethylene glycol diacrylate component is therefore between 5% and 15% wt.

In Table 4 we can, in addition, observe that the decrease of Sartomer 348 in the composition from 40% to 20% wt produces a slight increase of the flexibility and toughness of the objects produced with the resin composition. We found that an optimal concentration of the ethoxylated Bisphenol methacrylate component is between 20% and 50% wt.

The resin composition comprises 0.5-5% by weight of a photo initiator required for UV cure. One photo initiator (Irgacure 651) with high extinction coefficient at short wavelength is used for surface cure and another photo initiator (Lucirin TPO) with low to moderate extinction coefficient at longer wavelength is used for through cure.

Tables 2-4 point out surprisingly that at least one, preferably two different methacrylate components with at least one, preferably two different acrylate components, and a photoinitiator may form a performing resin composition exhibiting high green strength, good mechanical properties, high toughness, low curling and shrinkage, and being in particular very well suited to be cured with an acceptable speed in an stereo lithography apparatus SA as described above, supplying low intensity incoherent radiation to the illumination area IA.

Tables 2-4 point out, furthermore, that unexpectedly a resin composition comprising:
(A1) 5-15% by weight of at least a polyethylenglycol diacrylate
(A2) 5-15% by weight of at least a cycloaliphatic diacrylate
(B) 20-50% by weight of at least an aliphatic urethane methacrylate
(C) 0.5-5% by weight of at least a photo initiator allows high green strength, high toughness, low curling and shrinkage and optimal mechanical properties to be achieved with an acceptable reaction speed under the curing conditions as provided by the stereo lithography apparatus SA as described above, supplying low intensity incoherent radiation to the illumination area IA.

Table 5 shows a resin composition (Example 15) according to the present invention without multifunctional thiols and a resin composition (Example 16) according to the present invention comprising 5% wt of a multifunctional thiol (PETMP).

The viscosity of said resin compositions, the green strength of the objects produced by curing the corresponding resins and the mechanical properties of the three-dimensional objects OB obtained after post curing have been indicated in Table 5 for each resin composition.

In Table 5 we can observe that the increase of PETMP in the composition from 0% to 5% wt produces an improvement of all mechanical properties, a dramatic unexpected and surprising increase in the green strength from 50 to 650 MPa, a notable increase in the toughness (K1c, G1c) and also a notable increase of the critical exposure (Ec). At the same time, the shrinkage is unexpectedly drastically reduced (from 315 to 248 microns).

We have surprisingly found that concentrations of multifunctional thiols between 0.1% and 10% wt, preferably between 1% and 8% wt, more preferably between 2% and 7% wt in methacrylate and acrylate based resin compositions can dramatically increase the green strength and toughness and reduce the shrinkage of the three-dimensional objects OB produced by their curing, leading to resin compositions optimally suited to be cured in a stereo lithography apparatus SA as described above, supplying low intensity incoherent radiation to the illumination area IA.

Table 6 shows different resin compositions according to the present invention, whereby the multifunctional thiol PETMP is varied between 0 and 9% by weight (Examples 17-20).

The viscosity of said resin compositions and the mechanical properties of the three-dimensional objects OB obtained after post curing have been indicated in Table 6 for each resin composition.

In Table 6 we can observe that the increase of PETMP in the composition from 0% to 9% wt produces a dramatic surprising increase in the toughness (K1c, G1c). The tensile modulus, the tensile strength and the flexural strength exhibit surprisingly a maximum at 5% wt of PETMP, which seems to be therefore the most favourable concentration value of the multifunctional thiol component.

We have therefore unexpectedly found that concentrations of multifunctional thiols between 0.1% and 10% wt, preferably between 1% and 8% wt, more preferably between 2% and 7% wt can dramatically increase the toughness and maximize the tensile modulus, the tensile strength and the flexural strength of the three-dimensional objects OB produced by curing of the corresponding resin, leading to resin compositions optimally suited to be cured in a stereo lithography apparatus SA as described above, supplying low intensity incoherent radiation to the illumination area IA.

Table 7 shows resin compositions according to the present invention, whereby the multifunctional thiol type is varied and present at 5% weight (Examples 21-27). The different used multifunctional thiol types are listed in Table 1a. Independently from the type of the multifunctional thiol, we can unexpectedly observe that resins comprising a multifunctional thiol exhibit a dramatic increase in toughness (K1c and G1c) compared to resins without multifunctional thiols (Example 15). Surprisingly, resins comprising a multifunctional thiol exhibit also advantageously higher tensile modulus, strength and elongation at break compared to resins without multifunctional thiols (Example 15).

TABLE 2

| | | Example Number | | | | |
|---|---|---|---|---|---|---|
| | | 1 | 2 | 3 | 4 | 5 |
| Acrylates | Sartomer 349 % wt | 8 | 8.7 | 7.8 | 7 | 5 |
| | Sartomer 833s % wt | 8 | | 10 | 20 | 40 |
| | Sartomer 344 % wt | 8 | 8.7 | 7.8 | 7 | 5 |
| Methacrylates | Sartomer 348C % wt | 40 | 43.5 | 39.1 | 34 | 25.5 |
| | Genomer 4205 % wt | 33 | 36.1 | 32.3 | 28.5 | 21.5 |
| Photoinitiators | Lucirin TPO % wt | 1 | 1 | 1 | 1 | 1 |
| | Irgacure 651 % wt | 2 | 2 | 2 | 2 | 2 |
| Total % weight | | 100 | 100 | 100 | 100 | 100 |

| | | | | | |
|---|---|---|---|---|---|
| Viscosity 30° C. (mPa s) | 670 | 820 | 650 | 510 | 340 |
| Green Strength (MPa) | 40 | 40 | 40 | 40 | 50 |
| Tensile Modulus (MPa) | 2450 | 2500 | 2550 | 2650 | 2700 |
| Tensile Strength (MPa) | 47 | 48 | 52 | 42 | 36 |
| Elongation at break (%) | 2.5 | 2.5 | 3 | 2 | 1.5 |
| Bend Modulus (MPa) | 2300 | 2350 | 2300 | 2450 | 2600 |
| Flexural strength at 3.5% (MPa) | 80 | 80 | 80 | 80 | 90 |
| Maximum Flexural Strength (MPa) | 90 | 85 | 95 | 100 | 95 |
| K1c (MPa · \sqrt{m}) | 0.7 | 0.7 | 0.7 | 0.65 | 0.55 |
| G1c (J · m²) | 190 | 170 | 180 | 150 | 100 |
| HDT at 1.80 MPa (° C.) | 55 | 55 | 56 | 57 | 60 |
| HDT at 0.45 MPa (° C.) | 68 | 66 | 69 | 72 | 86 |

TABLE 3

| | | Example Number | | | |
|---|---|---|---|---|---|
| | | 6 | 7 | 8 | 9 |
| Acrylates | Sartomer 349 % wt | 12 | 11 | 9.5 | 7 |
| | Sartomer 833s % wt | 12 | 11 | 9.5 | 7 |
| | Sartomer 344 % wt | 12 | 11 | 9.5 | 7 |
| Methacrylates | Sartomer 348C % wt | 61 | 54 | 48.5 | 36 |
| | Genomer 4205 % wt | | 10 | 20 | 40 |
| Photoinitiators | Lucirin TPO % wt | 1 | 1 | 1 | 1 |
| | Irgacure 651 % wt | 2 | 2 | 2 | 2 |
| Total % weight | | 100 | 100 | 100 | 100 |

| | | | | |
|---|---|---|---|---|
| Viscosity 30° C. (mPa s) | 290 | 350 | 470 | 680 |
| Green Strength (MPa) | 35 | 35 | 55 | 35 |
| Tensile Modulus (MPa) | 2450 | 2400 | 2500 | 2350 |
| Tensile Strength (MPa) | 47 | 43 | 44 | 45 |
| Elongation at break (%) | 2.5 | 2 | 2 | 2.5 |
| Bend Modulus (MPa) | 2150 | 2200 | 2400 | 2350 |
| Flexural strength at 3.5% (MPa) | 75 | 75 | 85 | 80 |
| Maximum Flexural Strength (MPa) | 85 | 95 | 95 | 100 |
| K1c (MPa · √m) | 0.65 | 0.7 | 0.65 | 0.7 |
| G1c(J · m²) | 170 | 180 | 150 | 190 |

TABLE 4

| | | Example Number | | | | |
|---|---|---|---|---|---|---|
| | | 10 | 11 | 12 | 13 | 14 |
| Acrylates | Sartomer 349 % wt | | 20 | 8.7 | 7 | 10.8 |
| | Sartomer 833s % wt | 8.7 | 7 | 8.7 | 7 | 10.8 |
| | Sartomer 344 % wt | 8.7 | 7 | | 20 | 10.8 |
| Methacrylates | Sartomer 348C % wt | 43.6 | 34.5 | 43.6 | 34.5 | 20 |
| | Genomer 4205 % wt | 36 | 28.5 | 36 | 28.5 | 44.6 |
| Photoinitiators | Lucirin TPO % wt | 1 | 1 | 1 | 1 | 1 |
| | Irgacure 651 % wt | 2 | 2 | 2 | 2 | 2 |
| Total % weight | | 100 | 100 | 100 | 100 | 100 |

| | | | | | |
|---|---|---|---|---|---|
| Viscosity 30° C. (mPa s) | 570 | 580 | 880 | 330 | 620 |
| Green Strength (MPa) | 100 | 40 | 45 | 25 | 40 |
| Tensile Modulus (MPa) | 2500 | 2600 | 2700 | 2050 | 2350 |
| Tensile Strength (MPa) | 48 | 48 | 48 | 42 | 48 |
| Elongation at break (%) | 2.5 | 2.5 | 2.0 | 3 | 2.5 |
| Bend Modulus (MPa) | 2350 | 2400 | 2600 | 1950 | 2200 |
| Flexural strength at 3.5% (MPa) | 80 | 85 | 95 | 70 | 75 |
| Maximum Flexural Strength (MPa) | 100 | 105 | 105 | 85 | 90 |
| k1c (MPa · \sqrt{m}) | 0.75 | 0.8 | 0.6 | 0.8 | 0.8 |
| G1c (J · m²) | 190 | 210 | 110 | 270 | 265 |
| HDT at 1.80 MPa (° C.) | — | 54 | 57 | 52 | 53 |
| HDT at 0.45 MPa (° C.) | 70 | 65 | 73 | 63 | 65 |

TABLE 5

| | | Example Number | |
|---|---|---|---|
| | | 15 | 16 |
| Acrylates | Sartomer 349 % wt | 6 | 5.6 |
| | Sartomer 833s % wt | 9 | 8.5 |
| | Sartomer 344 % wt | 9 | 8.5 |
| Methacrylates | Sartomer 348C % wt | 40 | 37.9 |
| | Genomer 4205 % wt | 33 | 31.4 |
| Photoinitiators | Lucirin TPO % wt | 1 | 1 |
| | Irgacure 651 % wt | 2 | 2 |
| Thiol | PETMP % wt | | 5 |
| Stabiliser | Wako Q1301 % wt | | 0.1 |
| Total % weight | | 100 | 100 |

| | | |
|---|---|---|
| Viscosity 30° C. (mPa s) | 650 | 600 |
| Green Strength (MPa) | 50 | 650 |
| Tensile Modulus (MPa) | 1900 | 2300 |
| Tensile Strength (MPa) | 38 | 48 |
| Elongation at break (%) | 3 | 4.5 |
| Bend Modulus (MPa) | 1850 | 2150 |
| Flexural strength at 3.5% (MPa) | 66 | 72 |
| Maximum Flex.I Strength (MPa) | 80 | 81 |
| K1c (MPa · √m) | 0.8 | 1.2 |
| G1c(J · m²) | 300 | 500 |
| HDT at 1.80 MPa (° C.) | 50 | 52 |
| HDT at 0.45 MPa (° C.) | 62 | 59 |
| Dp (microns)* | 300 | 320 |
| Ec (mJ/cm²)* | 4.9 | 10.6 |
| Shrinkage (H-Bench, microns) | 300 | 250 |
| Shrinkage (Volume %, moulds) | 5.3 | 4.8 |

TABLE 6

| | | Example Number | | | |
|---|---|---|---|---|---|
| | | 17 | 18 | 19 | 20 |
| Acrylates | Sartomer 349 | 40 | 39.2 | 37.9 | 36.2 |
| | % wt | | | | |
| | Sartomer 833s | | | | |
| | % wt | | | | |
| | Sartomer 344 | | | | |
| | % wt | | | | |
| | CN 981 % wt | 15 | 14.6 | 14.1 | 13.5 |
| Methacrylates | Sartomer 348C | 30 | 29.4 | 28.5 | 27.2 |
| | % wt | | | | |
| | Genomer 4205 | 10 | 9.8 | 9.5 | 9.1 |
| | % wt | | | | |
| Photoinitiators | Lucirin TPO | 1.5 | 1.5 | 1.5 | 1.5 |
| | % wt | | | | |
| | Irgacure 651 | 3.5 | 3.5 | 3.5 | 3.5 |
| | % wt | | | | |
| Thiol | PETMP % wt | | 2 | 5 | 9 |

| | | | | |
|---|---|---|---|---|
| Total % weight | 100 | 100 | 100 | 100 |
| Viscosity 30° C. (mPa s) | 1400 | 1350 | 1350 | 1300 |
| Tensile Modulus (MPa) | 1950 | 2100 | 2450 | 2150 |
| Tensile Strength (MPa) | 41 | 48 | 52 | 47 |
| Elongation at break (%) | 3 | 4 | 4.5 | 5.5 |
| Bend Modulus (MPa) | 2050 | 1750 | 2000 | 1950 |
| Flexural strength at 3.5% (MPa) | 69 | 59 | 71 | 68 |
| Maximum Flexural Strength (MPa) | 82 | 67 | 84 | 84 |
| K1c (MPa · √m) | 0.8 | 0.75 | 1.1 | 1.6 |
| G1c(J · m²) | 250 | 250 | 450 | 1100 |
| HDT at 1.80 MPa (° C.) | 46 | 46 | 46 | 42 |

TABLE 7

| | | Example Number | | | | | | | |
|---|---|---|---|---|---|---|---|---|---|
| | | 21 | 22 | 23 | 24 | 25 | 26 | 27 | 28 |
| Acrylates | Sartomer 349 % wt | 5.7 | 5.7 | 5.7 | 5.7 | 5.7 | 5.7 | 5.7 | 5.6 |
| | Sartomer 833s % wt | 8.5 | 8.5 | 8.5 | 8.5 | 8.5 | 8.5 | 8.5 | 8.5 |
| | Sartomer 344 % wt | 8.5 | 8.5 | 8.5 | 8.5 | 8.5 | 8.5 | 8.5 | 8.5 |
| Methacrylates | Sartomer 348C % wt | 37.9 | 37.9 | 37.9 | 37.9 | 37.9 | 37.9 | 37.9 | 37.9 |
| | Genomer 4205 % wt | 31.3 | 31.3 | 31.3 | 31.3 | 31.3 | 31.3 | 31.3 | 31.4 |
| Photoinitiators | Lucirin TPO % wt | 1 | 1 | 1 | 1 | 1 | 1 | 1 | 1 |
| | Irgacure 651 % wt | 2 | 2 | 2 | 2 | 2 | 2 | 2 | 2 |
| Inhibitors | Wako Q1301 % wt | 0.10 | 0.10 | 0.10 | 0.10 | 0.10 | 0.10 | 0.10 | 0.1 |
| Thiols | TMPMP % wt | 5.00 | | | | | | | |
| | TMPMA % wt | | 5.00 | | | | | | |
| | GDMA % wt | | | 5.00 | | | | | |
| | GDMP % wt | | | | 5.00 | | | | |
| | PPGMP 800 % wt | | | | | 5.00 | | | |
| | ETTMP 1300 % wt | | | | | | 5.00 | | |
| | PETMA % wt | | | | | | | 5.00 | |
| | PETMB % wt | | | | | | | | 5.00 |
| Total % wt | | 100 | 100 | 100 | 100 | 100 | 100 | 100 | 100 |

| | | | | | | | | |
|---|---|---|---|---|---|---|---|---|
| Viscosity 30° C. (mPa s) | 540 | 540 | 420 | 450 | 510 | 550 | 580 | |
| Tensile Modulus (MPa) | 2350 | 2300 | 2250 | 2200 | 2100 | 1700 | 2200 | 2550 |
| Tensile Strength (MPa) | 53 | 49 | 48 | 48 | 47 | 40 | 49 | 51 |
| Elongation at break (%) | 4 | 4 | 6 | 4 | 4 | 4 | 5 | 4 |
| Bend Modulus (MPa) | 1700 | 1850 | 1800 | 1650 | 1600 | 1400 | 1800 | 2000 |
| Flexural strength at 3.5% (MPa) | 62 | 67 | 64 | 58 | 57 | 49 | 62 | |
| Maximum Flexural Strength (MPa) | 80 | 85 | 80 | 75 | 75 | 65 | 75 | |
| K1c (MPa · \sqrt{m}) | 1.4 | 1.3 | 1.6 | 1.5 | 1 | 0.9 | 1.3 | 0.7 |
| G1c (J · m²) | 900 | 800 | 1200 | 1200 | 500 | 500 | 800 | 200 |
| HDT at 1.80 MPa (° C.) | 50 | 49 | 45 | 47 | 51 | 48 | 45 | |
| HDT at 0.45 MPa (° C.) | 56 | 54 | 50 | 53 | 63 | 57 | 54 | 59 |
| Shrinkage (Volume %, moulds) | 4 | 5 | 5.5 | 3.5 | 5 | 4.5 | 4 | |

1. System comprising:
(a) an apparatus for producing a three-dimensional object from a light-sensitive material, said apparatus comprising:
an exposure system (ES) with an illumination source,
a control unit (CU),
whereby said exposure system (ES) comprises:
at least one spatial light modulator (SLM) with a plurality of individually controllable light modulators (LM),
input optics (IO) optically coupled to said at least one spatial light modulator (SLM), output optics (OO) optically coupled to said at least one spatial light modulator (SLM),
wherein said input optics (IO) and output optics (OO) facilitates transmission of light emitted from said illumination source via said individually controllable light modulators (LM) of said spatial light modulator (SLM) to an illumination area (IA),
wherein said spatial light modulator (SLM) enables an establishment of a pattern of the light transmitted through said input optics (IO), according to control signals originating from said control unit (CU),
wherein said output optics (OO) enable focusing of the pattern of light from said at least one spatial light modulator (SLM) on an illumination area (IA); and
(b) a resin composition comprising:
(A) at least one acrylate component,
(B) at least one methacrylate component,
(C) a photo initiator.

2. A system according to claim 1, wherein the apparatus comprises a scanning bar to which the exposure system (ES) is mounted and/or wherein the distance d between the output optics (OO) and the illumination area (IA) is between 0.5 and 20 mm and/or wherein the illumination source generates incoherent light.

3. A system according to any of the preceding claims, wherein the resin composition comprises:
(A) 15-40% by weight of at least two different acrylate components
(B) 50-80% by weight of at least two different methacrylate components
(C) 0.1-7% by. weight. of a photo initiator
based on the total weight of the resin composition.

4. A system according to any of the preceding claims, wherein an acrylate component is an aliphatic or cycloaliphatic acrylate, preferably a cycloaliphatic diacrylate, or any mixture thereof.

5. A system according to any of the preceding claims, wherein an acrylate component is a polyethylenglycol acrylate, preferably a polyethylenglycol diacrylate.

6. A system according to any of the preceding claims, wherein a methacrylate component is an aliphatic urethane methacrylate.

7. A system according to any of the preceding claims, wherein a methacrylate component is an ethoxylated bisphenol methacrylate, preferably an ethoxylated bisphenol dimethacrylate.

8. A system according to any of the preceding claims wherein the resin composition additionally comprises one or more multifunctional thiols, preferably in an amount of 0.1-10% by weight, more preferably in an amount of 1-8% by weight based on the total weight of the composition.

9. A system according to any of the preceding claims, wherein the resin composition additionally comprises a stabilizer, preferably a N-nitroso hydroxyl amine complex with the structure: 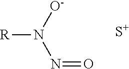
whereby R is an hydrocarbon aromatic rest and S⁺ is a salt.

10. A system according to claim 9, in which the N-nitroso hydroxyl amine complex is an aluminium salt complex.

11. A resin composition comprising:
(A) an acrylate component
(B) an aliphatic urethane methacrylate component
(C) a photo initiator.

12. A resin composition according to claim 11 comprising:
(A) a polyethylenglycol diacrylate or a cycloaliphatic diacrylate or any mixture thereof and/or
(D) a multifunctional thiol.

13. A resin composition according to claim 11 or 12 comprising:
(A) 5-60% by weight of at least one acrylate component, preferably polyethylenglycol diacrylate or a cycloaliphatic diacrylate or any mixture thereof
(B) 20-50% % by weight of at least one aliphatic urethane methacrylate component
(C) 0.5-5% by weight of a photo initiator
(D) optionally a multifunctional thiol
based on the total weight of the composition.

14. A resin composition according to claim 11 or 12 or 13 comprising at least:
(A1) 5-15% by weight of one or more polyethylenglycol diacrylates
(A2) 5-15% by weight of one or more aliphatic or cycloaliphatic diacrylates
(B1) 20-50% % by weight of one or more aliphatic urethane methacrylates
(B2) 20-50% % by weight of one or more ethoxylated bisphenol methacrylates
(C) 0.5-5% by weight of a photo initiator
(D) 0.1-10% by weight of one or more multifunctional thiols
(E) 0.01 to 0.5% % by weight of one or more stabilizers
based on the total weight of the composition.

15. Method for manufacturing a 3-dimensional object (OB) with a system according to any of the claims 1 to 10 and/or with a resin according to any of the claims 11 to 14, comprising the steps of:
a) producing a first layer of a liquid light-sensitive material;
b) exposing said first layer to UV radiation, so as to solidify said first layer with a predetermined pattern;
c) applying a second layer of a liquid light-sensitive material onto the first solidified layer;
d) exposing said second layer to UV radiation, so as to solidify said second layer with a predetermined pattern;
e) repeating the steps a) to d) until a predetermined 3-dimensional object (OB) is formed.

16 . A cured article obtained by a method according claim 15.

17. System according to any of the claims 1 to 10,
wherein the apparatus for producing a three-dimensional object from a light-sensitive material comprises at least one releasable protective window (PW) between said output optics (OO) and said illumination area (IA).

18. System according to any of the claim 1 to 10 or 17,
wherein the apparatus for producing a three-dimensional object from a light-sensitive material comprises at least one collision-preventing detection system (LBa, LBb, HSa, HSb) for detecting obstacles between the illumination area (IA) and the output optics (OO).
